(19) United States
(12) Patent Application Publication
(10) Pub. No.: US 2017/0373062 A1
(43) Pub. Date: Dec. 28, 2017

(54) Semiconductor Device and Method for Fabricating the Same

(71) Applicant: Samsung Electronics Co., Ltd., Suwon-si (KR)

(72) Inventors: Moon Seung Yang, Hwaseong-si (KR); Dong Chan SUH, Suwon-si (KR); Chul KIM, Seongnam-si (KR); Woo Bin SONG, Hwaseong-si (KR); Ji Eon YOON, Hwaseong-si (KR); Seung Ryul LEE, Seoul (KR)

(21) Appl. No.: 15/494,769

(22) Filed: Apr. 24, 2017

(30) Foreign Application Priority Data
Jun. 23, 2016 (KR) 10-2016-0078593

(51) Int. Cl. H01L 27/092; H01L 29/06; H01L 29/10; H01L 29/78

(52) U.S. Cl. CPC H01L 27/092; H01L 29/785; H01L 29/0669; H01L 29/1033

(57) ABSTRACT

The semiconductor device includes a first multi-channel active pattern protruding from a substrate, and having a first height, a second multi-channel active pattern on the substrate, being spaced apart from the substrate, and having a second height that is less than the first height, and a gate electrode on the substrate, intersecting the first multi-channel active pattern and the second multi-channel active pattern.

### CROSS-REFERENCE TO RELATED APPLICATION

This application claims priority from Korean Patent Application No. 10-2016-0078593 filed on Jun. 23, 2016 in the Korean Intellectual Property Office, and all the benefits accruing therefrom under 35 U.S.C. 119, the contents of which in its entirety are herein incorporated by reference.

### BACKGROUND

The present disclosure relates to semiconductor devices and methods for fabricating the same.

For semiconductor device density enhancement, a multigate transistor has been suggested as one of the scaling technologies, according to which a multi-channel active pattern (or silicon body) in a fin or nanowire shape is formed on a substrate. Gates may then be formed on a surface of the multi-channel active pattern.

A multigate transistor may allow easy scaling, as it may use a three-dimensional channel. Further, current control capability can be enhanced without requiring increased gate length of the multigate transistor. Furthermore, it is possible to effectively suppress short channel effect (SCE) which is the phenomenon that the electric potential of the channel region is influenced by the drain voltage.

### SUMMARY

A technical objective of the present disclosure is to provide semiconductor devices comprising a mandrel including semiconductor material and epitaxial channel patterns disposed in both sides of the mandrel.

Another technical objective of the present disclosure is to provide methods for fabricating a semiconductor device, which is capable of forming a mandrel including semiconductor material and epitaxial channel patterns by using epitaxial layer extending along a hard mask pattern on the mandrel.

The objects according to the present disclosure are not limited to those set forth above and objects other than those set forth above will be clearly understood to a person skilled in the art from the following description.

According to an aspect of the present inventive concept, there is provided a semiconductor device comprising a first multi-channel active pattern protruding from a substrate, and having a first height; a second multi-channel active pattern on the substrate, being spaced apart from the substrate, and having a second height that is less than the first height; and a gate electrode on the substrate, intersecting the first multi-channel active pattern and the second multi-channel active pattern.

According to another aspect of the present inventive concept, there is provided a semiconductor device comprising a first multi-channel active pattern having a first height on a substrate; a second multi-channel active pattern on the substrate, having a second height that is less than the first height; a field insulating film on the substrate, partially covering a sidewall of the first multi-channel active pattern and a sidewall of the second multi-channel active pattern; and a gate electrode on the field insulating film, intersecting the first multi-channel active pattern and the second multi-channel active pattern, wherein a height from the substrate to an uppermost portion of the first multi-channel active pattern is equal to or less than a height from the substrate to an uppermost portion of the second multi-channel active pattern.

According to another aspect of the present inventive concept, a semiconductor device includes a first multi-channel active pattern having a first height on a substrate, the first multi-channel active pattern being spaced apart from the substrate, and a second multi-channel active pattern having a second height on the substrate, the second multi-channel active pattern being spaced apart from the substrate, the second height being different from the first height. The semiconductor device may include a field insulating film on the substrate, covering a sidewall of the first multi-channel active pattern and a sidewall of the second multi-channel active pattern, interposed between the second multi-channel active pattern and the substrate, and a gate electrode on the substrate, intersecting the first multi-channel active pattern and the second multi-channel active pattern.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIG. 1 is a schematic top view provided to explain a semiconductor device according to some example embodiments;

FIG. 2 is a cross sectional view taken on line A-A of FIG. 1;

FIG. 3 is a view of FIG. 2 from which the first gate electrode and the first gate insulating film are omitted;

FIG. 4 is a cross sectional view taken on line B-B of FIG. 1;

FIG. 5 is a view provided to explain a semiconductor device according to some example embodiments;

FIG. 6 is a view provided to explain a semiconductor device according to some example embodiments;

FIG. 7 is a view provided to explain a semiconductor device according to some example embodiments;

FIG. 8 is a view provided to explain a semiconductor device according to some example embodiments of the present disclosure;

FIG. 9 is a schematic top view provided to explain a semiconductor device according to some example embodiments;

FIG. 10 is a cross sectional view taken on line C-C of FIG. 9;

FIG. 11 is a schematic top view provided to explain a semiconductor device according to some example embodiments;

FIG. 12 is a cross sectional view taken on lines A-A and D-D of FIG. 11;

FIG. 13 is a view provided to explain a semiconductor device according to some example embodiments;

FIG. 14 is a view provided to explain a semiconductor device according to some example embodiments;

FIG. 15 is a schematic top view provided to explain a semiconductor device according to some example embodiments;

FIG. 16 is a cross sectional view taken on lines A-A and D-D of FIG. 15;

FIGS. 17 to 26 are views illustrating intermediate stages of fabrication, provided to explain methods for fabricating a semiconductor device according to some example embodiments;

FIGS. 27 to 30 are views illustrating intermediate stages of fabrication, provided to explain methods for fabricating a semiconductor device according to some example embodiments;

FIGS. 31 and 32 are views illustrating intermediate stages of fabrication, provided to explain methods for fabricating a semiconductor device according to some example embodiments;

FIGS. 33A to 37 are views illustrating intermediate stages of fabrication, provided to explain methods for fabricating a semiconductor device according to some example embodiments; and

FIGS. 38 to 43 are views illustrating intermediate stages of fabrication, provided to explain methods for fabricating a semiconductor device according to some example embodiments.

### DETAILED DESCRIPTION

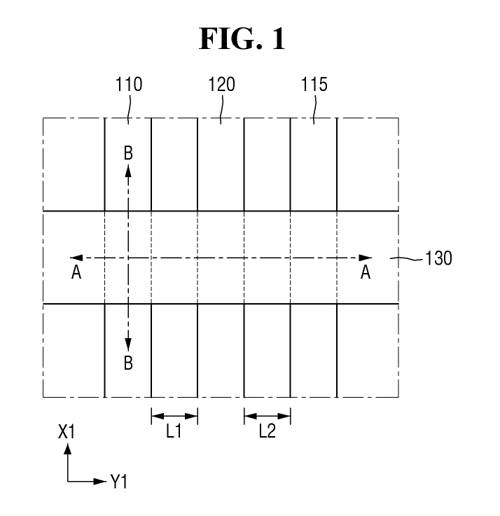

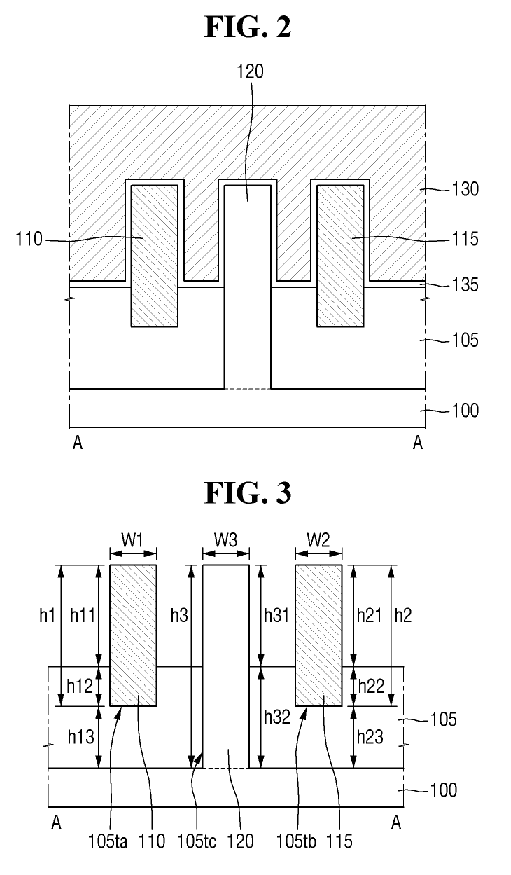

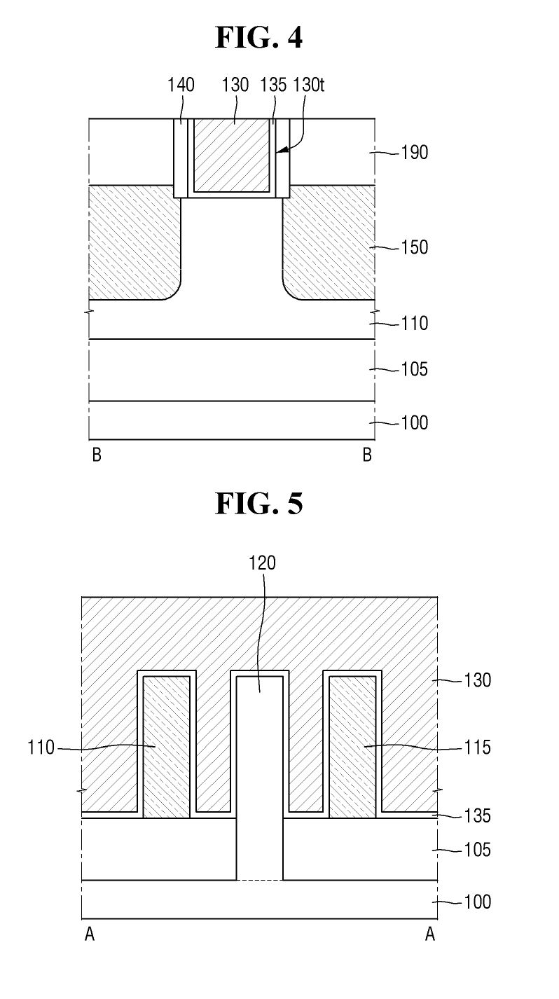

FIG. 1 is a schematic top view provided to explain a semiconductor device according to some example embodiments of the present disclosure. FIG. 2 is a cross sectional view taken on line A-A of FIG. 1. FIG. 3 is a view of FIG. 2 from which the first gate electrode and the first gate insulating film are omitted. FIG. 4 is a cross sectional view taken on line B-B of FIG. 1.

Referring to FIGS. 1 to 4, a semiconductor device according to some example embodiments may include a field insulating film 105, a first epitaxial channel pattern 110, a second epitaxial channel pattern 115, a first mandrel channel pattern 120, and a first gate electrode 130.

The substrate 100 may be a silicon substrate, or may include other material such as silicon germanium, indium antimonide, lead telluride compound, indium arsenide, indium phosphide, gallium arsenide, and/or gallium antimonide. In some embodiments, the substrate 100 may be a base substrate having an epitaxial layer formed thereon.

The first mandrel channel pattern 120 may protrude from the substrate 100. The first mandrel channel pattern 120 may be elongated in a first direction X1.

As illustrated in FIGS. 2 and 3, the first mandrel channel pattern 120 may be directly connected to the substrate 100, although example embodiments are not limited thereto. A semiconductor region may be further disposed between the first mandrel channel pattern 120 and the substrate 100 to connect the first mandrel channel pattern 120 to the substrate 100.

Each of the first epitaxial channel pattern 110 and the second epitaxial channel pattern 115 may spatially be spaced apart from the substrate 100. The first epitaxial channel pattern 110 and the second epitaxial channel pattern 115 may not be directly connected to the substrate 100. Further, the first epitaxial channel pattern 110 and the second epitaxial channel pattern 115 may not be directly connected to the substrate 100 through the semiconductor region.

Each of the first epitaxial channel pattern 110 and the second epitaxial channel pattern 115 may be elongated in the first direction X1. The first mandrel channel pattern 120 may be located between the first epitaxial channel pattern 110 and the second epitaxial channel pattern 115.

In a semiconductor device according to some example embodiments, a distance L1 between the first epitaxial channel pattern 110 and the first mandrel channel pattern 120 may be substantially the same as a distance L2 between the second epitaxial channel pattern 115 and the first mandrel channel pattern 120.

In a semiconductor device according to some example embodiments, the first mandrel channel pattern 120, the first epitaxial channel pattern 110, and the second epitaxial channel pattern 115 may be a multi-channel active pattern, respectively. For example, the first mandrel channel pattern 120, the first epitaxial channel pattern 110, and the second epitaxial channel pattern 115 may each be a fin-type pattern.

The first mandrel channel pattern 120 may be a part of the substrate 100, and may include an epitaxial layer grown from the substrate 100.

The first mandrel channel pattern 120 may include an element semiconductor material such as silicon or germanium, for example. Further, the first mandrel channel pattern 120 may include a compound semiconductor such as, for example, IV-IV group compound semiconductor or III-V group compound semiconductor.

Specifically, take the IV-IV group compound semiconductor for instance, the first mandrel channel pattern 120 may be a binary compound or a ternary compound including, for example, at least two or more of carbon (C), silicon (Si), germanium (Ge), and/or tin (Sn), or the such binary or ternary compound doped with IV group element.

Take the III-V group compound semiconductor for instance, the first mandrel channel pattern 120 may be one of a binary compound, a ternary compound or a quaternary compound which is formed by a combination of a III group element which may be at least one of aluminum (Al), gallium (Ga), and/or indium (In), with a V group element which may be one of phosphorus (P), arsenic (As) and/or antimony (Sb).

In a semiconductor device according to some example embodiments, the first epitaxial channel pattern 110 and the second epitaxial channel pattern 115 may each include the same semiconductor material as the first mandrel channel pattern 120.

The field insulating film 105 may be formed on the substrate 100. The field insulating film 105 may partially cover a sidewall of the first mandrel channel pattern 120. The field insulating film 105 is not interposed between the first mandrel channel pattern 120 and the substrate 100. That is, the field insulating film 105 is not interposed between a lowermost portion of the first mandrel channel pattern 120 and the substrate 100.

The first epitaxial channel pattern 110 and the second epitaxial channel pattern 115 may each be formed on the field insulating film 105. In other words, the field insulating film 105 may be interposed between the first epitaxial channel pattern 110 and the substrate 100, and between the second epitaxial channel pattern 115 and the substrate 100.

A field insulating film 105 may cover a portion of a sidewall of the first epitaxial channel pattern 110 and a portion of a sidewall of the second epitaxial channel pattern 115.

An upper surface of the first mandrel channel pattern 120, an upper surface of the first epitaxial channel pattern 110, and an upper surface of the second epitaxial channel pattern 115 may each protrude upward further than an upper surface of the field insulating film 105.

The field insulating film 105 may include, for example, one of oxide film, nitride film, oxynitride film, and/or a combination thereof.

Further, the field insulating film 105 may additionally include at least one field liner film formed between the first mandrel channel pattern 120 and the field insulating film 105.

When the field insulating film 105 further includes the field liner film and the first mandrel channel pattern 120 includes silicon, the field liner film may include at least one of polysilicon, amorphous silicon, silicon oxynitride, silicon nitride, and/or silicon oxide. Of course, the field liner film may vary depending on the materials included in the first mandrel channel pattern 120.

The height and width of the first mandrel channel pattern 120, the first epitaxial channel pattern 110 and the second epitaxial channel pattern 115 will be explained with reference to FIG. 3. Additionally, the positional relation between the first mandrel channel pattern 120, the first epitaxial channel pattern 110 and the second epitaxial channel pattern 115, and the field insulating film 105 will be explained.

A height h3 of the first mandrel channel pattern 120 may be greater than a height h1 of the first epitaxial channel pattern 110 and a height h2 of the second epitaxial channel pattern 115. The height h1 of the first epitaxial channel pattern 110 may be substantially the same as the height h2 of the second epitaxial channel pattern 115.

The field insulating film 105 may be interposed between the first epitaxial channel pattern 110 and the substrate 100, and between the second epitaxial channel pattern 115 and the substrate 100, but not between the first mandrel channel pattern 120 and the substrate 100. Accordingly, a height h12 at which the field insulating film 105 covers a sidewall of the first epitaxial channel pattern 110, and a height h22 at which the field insulating film 105 covers a sidewall of the second epitaxial channel pattern 115 are less than the height h32 at which the field insulating film 105 covers a sidewall of the first mandrel channel pattern 120.

However, the height h12 at which the field insulating film 105 covers the sidewall of the first epitaxial channel pattern 110 may be substantially the same as the height h22 at which the field insulating film 105 covers the sidewall of the second epitaxial channel pattern 115.

Additionally, the height h3 from the substrate 100 to the uppermost portion of the first mandrel channel pattern 120 may be equal to or less than the height h1+h13 from the substrate 100 to the uppermost portion of the first epitaxial channel pattern 110, and the height h2+h23 from the substrate 100 to the uppermost portion of the second epitaxial channel pattern 115.

Accordingly, the height h31 by which the first mandrel channel pattern 120 protrudes upward further than the upper surface of the field insulating film 105 may be equal to or less than the height h11 by which the first epitaxial channel pattern 110 and the height h21 of the second epitaxial channel pattern 115 protrude upward further than upper surface of the field insulating film 105.

However, the height h11 by which the first epitaxial channel pattern 110 protrudes upward further than the upper surface of the field insulating film 105 may be substantially the same as the height h21 by which the second epitaxial channel pattern 115 protrudes upward further than upper surface of the field insulating film 105.

A thickness h13 of the field insulating film 105 located between the first epitaxial channel pattern 110 and the substrate 100 may be substantially equal to a thickness h23 of the field insulating film 105 located between the second epitaxial channel pattern 115 and the substrate 100.

A width W1 of the first epitaxial channel pattern 110 may be substantially the same as a width W2 of the second epitaxial channel pattern 115. However, the width W1 of the first epitaxial channel pattern 110 may be the same as or different from a width W3 of the first mandrel channel pattern 120.

The field insulating film 105 may include first to third field trenches 105ta, 105tb and 105tc. A third field trench 105tc may be disposed between the first field trench 105ta and the second field trench 105tb.

A depth h32 of the third field trench 105tc may be greater than a depth h12 of the field trench 105ta and a depth h22 of the second field trench 105tb.

The first epitaxial channel pattern 110 may be disposed in the first field trench 105ta, and the second epitaxial channel pattern 115 may be disposed in the second field trench 105tb. The first mandrel channel pattern 120 may be formed in the third field trench 105tc.

The first gate electrode 130 may extend in a second direction Y1. The first gate electrode 130 may be formed on the field insulating film 105 formed on the substrate 100.

As illustrated in FIGS. 1 and 2, the first gate electrode 130 is illustrated as intersecting the first epitaxial channel pattern 110, the second epitaxial channel pattern 115, and the first mandrel channel pattern 120, but this is provided only for convenience of explanation and example embodiments are not limited thereto.

The first gate electrode 130 may surround the first epitaxial channel pattern 110, the second epitaxial channel pattern 115, and the first mandrel channel pattern 120 that protrude upward further than the upper surface of the field insulating film 105.

The first gate electrode 130 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof.

The first gate electrode 130 may include conductive metal oxide, conductive metal oxynitride or the like, and/or an oxidized form of the aforementioned material.

For example, the first gate electrode 130 may be formed by replacement process (or gate last process), but not limited thereto.

The gate spacer 140 may be formed on the sidewall of the first gate electrode 130. The gate spacer 140 may define the gate trench 130t.

The gate spacer 140 may include, for example, at least one of silicon nitride (SiN), silicon oxynitride (SiON), silicon oxide (SiO₂), silicon oxycarbonitride (SiOCN), and/or a combination thereof.

The first gate insulating film 135 may be formed along a profile of the first epitaxial channel pattern 110, the second epitaxial channel pattern 115, and the first mandrel channel pattern 120 that protrude upward further than the field insulating film 105. The first gate insulating film 135 may be extended along a sidewall and a bottom surface of the gate trench 130t.

The first gate electrode 130 may be formed in the gate trench 130t in which the first gate insulating film 135 is formed.

In addition, an interfacial layer may be further formed between the first gate insulating film 135 and the first epitaxial channel pattern 110, between the first gate insulating film 135 and the second epitaxial channel pattern 115, and between the first gate insulating film 135 and the first mandrel channel pattern 120.

The first gate insulating film 135 may include a high-k dielectric material having a higher dielectric constant than a silicon oxide film. For example, the first gate insulating film 135 may include one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

A source/drain region 150 may be formed on both sides of the first gate electrode 130. The source/drain region 150 may be formed on the first epitaxial channel pattern 110.

The source/drain region 150 may include an epitaxial pattern, but not limited thereto. Separate source/drain regions may be each formed on the second epitaxial channel pattern 115 in both sides of the first gate electrode 130, and on the first mandrel channel pattern 120 in both sides of the first gate electrode 130.

An interlayer insulating film 190 may be formed on the field insulating film 105. The interlayer insulating film 190 may cover the source/drain region 150. The interlayer insulating film 190 may surround a sidewall of the gate spacer 140.

For example, the interlayer insulating film 190 may include silicon oxide, silicon nitride, silicon oxynitride, flowable oxide (FOX), tonen silazene (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SILK, polyimide, porous polymeric material, and/or a combination thereof, but not limited thereto.

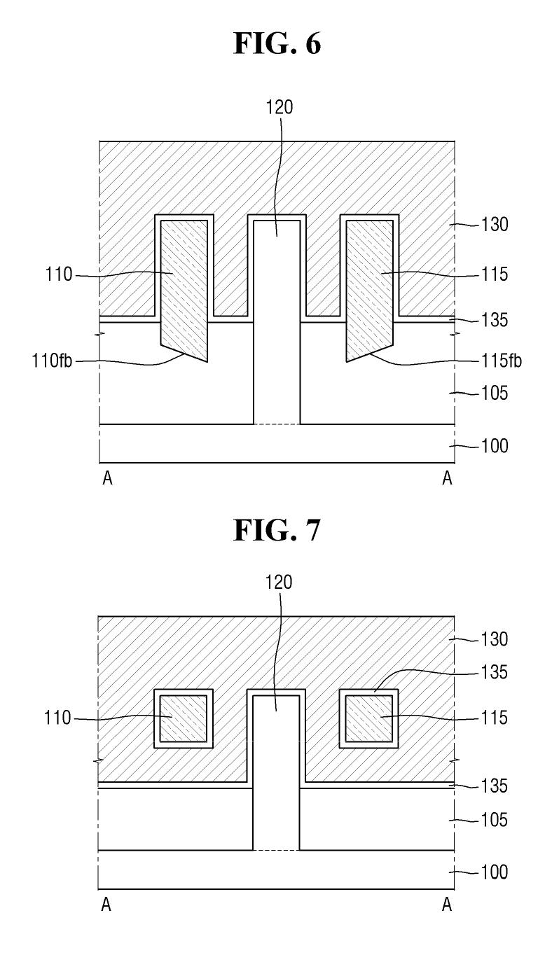

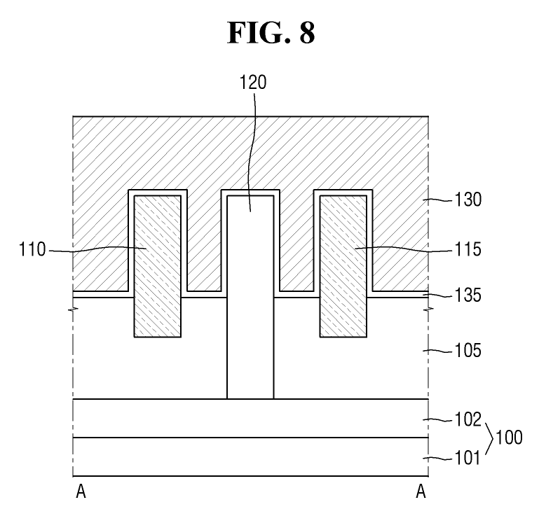

FIG. 5 is a view provided to explain a semiconductor device according to some example embodiments. FIG. 6 is a view provided to explain a semiconductor device according to some example embodiments. FIG. 7 is a view provided to explain a semiconductor device according to some example embodiments. FIG. 8 is a view provided to explain a semiconductor device according to some example embodiments of the present disclosure. For convenience of explanation, differences that are not explained above with reference to FIGS. 1 to 4 will be mainly explained below.

Referring to FIG. 5, in a semiconductor device according to some example embodiments, the field insulating film 105 may not cover the sidewall of the first epitaxial channel pattern 110 and the sidewall of the second epitaxial channel pattern 115.

A lowermost portion of the first epitaxial channel pattern 110 and a lowermost portion of the second epitaxial channel pattern 115 may be in contact with the field insulating film 105 on the field insulating film 105.

Referring to FIG. 6, in a semiconductor device according to some example embodiments, a lower surface of the first epitaxial channel pattern 110 may include a first facet 110fb.

Further, a lower surface of the second epitaxial channel pattern 115 may include a second facet 115fb.

Referring to FIG. 7, in a semiconductor device according to some example embodiments, the first gate insulating film 135 may be formed along a perimeter of the first epitaxial channel pattern 110 and a perimeter of the second epitaxial channel pattern 115.

The first gate electrode 130 may be formed so as to surround the perimeter of the first epitaxial channel pattern 110, and the perimeter of the second epitaxial channel pattern 115. The first gate electrode 130 may be interposed between the first epitaxial channel pattern 110 and the field insulating film 105, and between the second epitaxial channel pattern 115 and the field insulating film 105, but not limited thereto.

The first epitaxial channel pattern 110 and the second epitaxial channel pattern 115 are spatially spaced apart from the field insulating film 105. Each of the first epitaxial channel pattern 110 and the second epitaxial channel pattern 115 may not be in contact with the field insulating film 105.

The first mandrel channel pattern 120 is a fin-type pattern, but the first epitaxial channel pattern 110 and the second epitaxial channel pattern 115 may be a wire pattern in parallel with the upper surface of the field insulating film 105.

Referring to FIG. 8, in a semiconductor device according to some embodiments of the present disclosure, the substrate 100 may include a lower substrate 101 and an upper substrate 102 formed on one surface of the lower substrate 101.

For example, the lower substrate 101 may be a semiconductor substrate, and the upper substrate 102 may be an insulating film substrate.

The substrate 100 may include a semiconductor substrate and an insulating film substrate formed on one surface of the semiconductor substrate. For example, the substrate 100 may be a silicon on insulator (SOI), and/or a silicon-germanium on insulator (SGOI), but without limitation thereto.

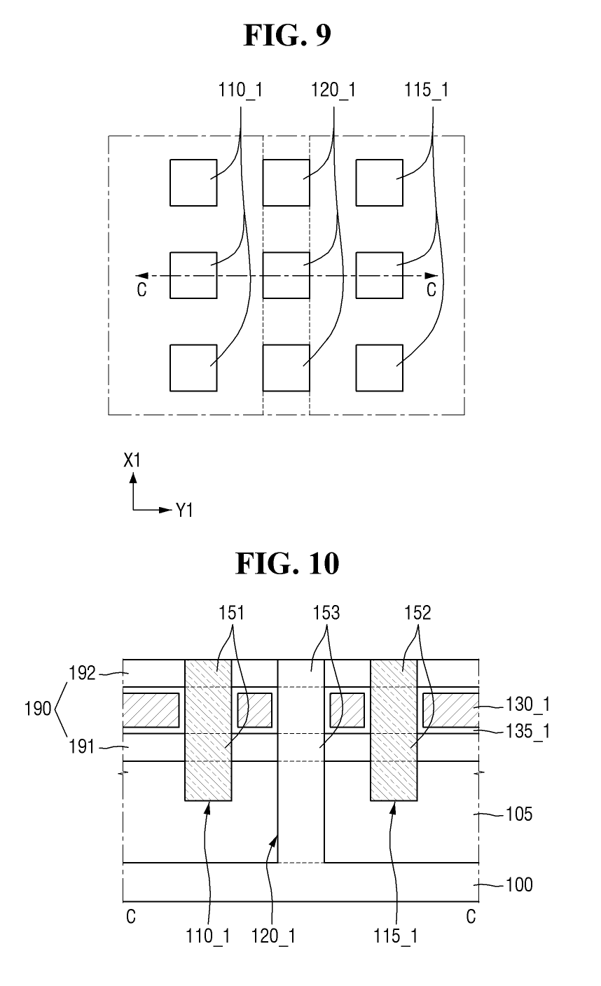

FIG. 9 is a schematic top view provided to explain a semiconductor device according to some embodiments of the present disclosure. FIG. 10 is a cross sectional view taken on line C-C of FIG. 9.

Regarding to FIG. 9, in a semiconductor device according to some example embodiments, a first vertical mandrel channel pattern 120_1, a first vertical epitaxial channel pattern 110_1 and a second vertical epitaxial channel pattern 115_1 may each be a wire pattern that is perpendicular to the upper surface of the field insulating film 105.

A plurality of first vertical mandrel channel patterns 120_1 may be arranged in the first direction X1. A plurality of first vertical epitaxial channel patterns 110_1 and a plurality of second vertical epitaxial channel patterns 115_1 may be arranged in the first direction X1.

The plurality of first vertical epitaxial channel patterns 110_1 and the plurality of second vertical epitaxial channel patterns 115_1 shown in FIG. 9 may be formed by patterning the first epitaxial channel pattern 110 and the second epitaxial channel pattern 115 in FIG. 1.

As illustrated in FIG. 9, the plurality of first vertical mandrel channel patterns 120_1 may connect to each other, the plurality of first vertical epitaxial channel patterns 110_1 may be separated apart from each other, and the plurality of a second vertical epitaxial channel patterns 115_1 may be separated apart from each other, but this is provided only for convenience of explanation and the example embodiments are not limited thereto.

A first vertical arrangement source/drain region 151 may be formed at both ends of each of the first vertical epitaxial channel patterns 110_1. A second vertical arrangement source/drain region 152 may be formed at both ends of each of the second vertical epitaxial channel patterns 115_1, and a third vertical arrangement source/drain region 153 may be formed at both ends of each of the first vertical mandrel channel patterns 120_1.

The first gate insulating film 135_1 and the first gate electrode 130_1 surrounding the first vertical mandrel channel patterns 120_1, the first vertical epitaxial channel patterns 110_1 and the second vertical epitaxial channel patterns 115_1 may be formed between each of the first vertical arrangement source/drain region 151, the second vertical source/drain region 152, and the third vertical source/drain region 153.

The interlayer insulating film 190 may include a lower interlayer insulating film 191 formed between the first gate electrode 130_1 and the field insulating film 105, and an upper interlayer insulating film 192 formed on the first gate electrode 130_1.

In FIG. 10, a shape in which the first gate insulating film 135_1 is formed is only for illustrative purpose and the example embodiments are not limited thereto. That is, the first gate insulating film 135_1 may not extend along the lower interlayer insulating film 191 and the upper interlayer insulating film 192.

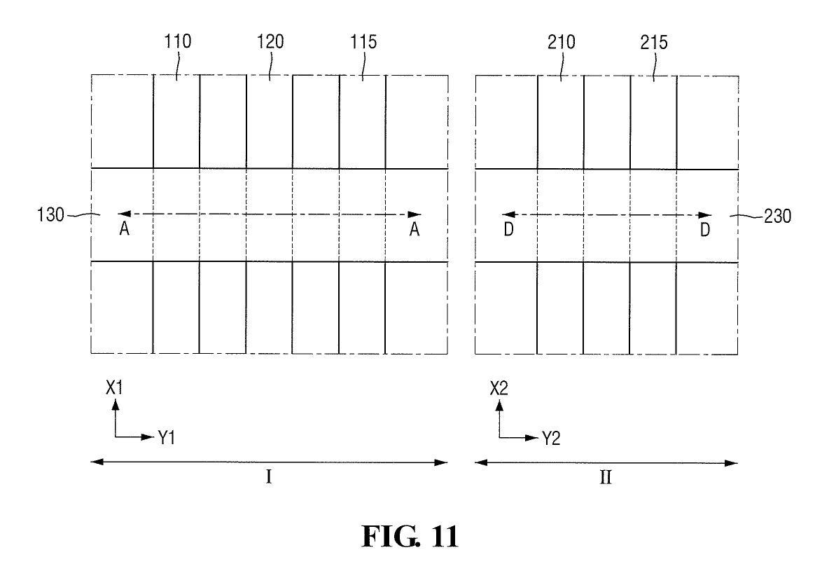

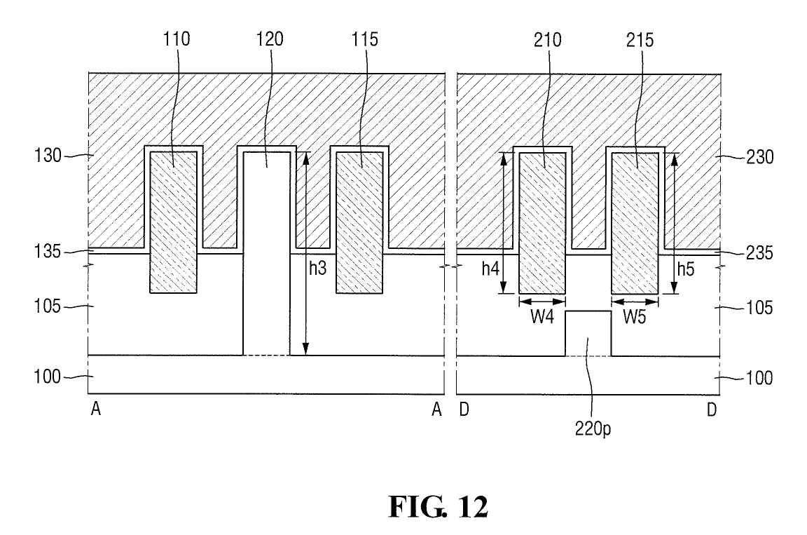

FIG. 11 is a schematic top view provided to explain a semiconductor device according to some embodiments of the present disclosure. FIG. 12 is a cross sectional view taken on lines A-A and D-D of FIG. 11.

For reference, the first region I in FIG. 11 will be described briefly, since some of the description would overlap with the description provided above with reference to FIGS. 1 to 4.

Referring to FIGS. 11 to 12, a semiconductor device according to some example embodiments may include a first epitaxial channel pattern 110, a second epitaxial channel pattern 115, a third epitaxial channel pattern 210, a fourth epitaxial channel pattern 215, a first mandrel channel pattern 120, a first gate electrode 130, and a second gate electrode 230.

The substrate 100 may include the first region I and the second region II. The first region I and the second region II may be spaced apart from each other, or connected to each other.

In a semiconductor device according to some example embodiments, different types of transistors may be formed in the first region I and the second region II. When the first conductivity type of transistor is formed in the first region I, the second conductivity type of transistor that is different from the first conductivity type may be formed in the second region II.

The first epitaxial channel pattern 110, the second epitaxial channel pattern 115, the first mandrel channel pattern 120, and the first gate electrode 130 may be formed in the first region I.

The third epitaxial channel pattern 210, the fourth epitaxial channel pattern 215, the second gate electrode 230 may be formed in the second region II.

Each of the third epitaxial channel pattern 210 and the fourth epitaxial channel pattern 215 may be elongated in the third direction X2. Each of the third epitaxial channel pattern 210 and the fourth epitaxial channel pattern 215 may spatially be spaced apart from the substrate 100.

The third epitaxial channel pattern 210 and the fourth epitaxial channel pattern 215 may include the same material as each other. However, the third epitaxial channel pattern 210 may include a different material from the first epitaxial channel pattern 110.

The third epitaxial channel pattern 210 and the fourth epitaxial channel pattern 215 may each include an element semiconductor material such as silicon and/or germanium, and include IV-IV group compound semiconductor and/or III-V group compound semiconductor.

The third epitaxial channel pattern 210 and the fourth epitaxial channel pattern 215 may each be a multi-channel active pattern. For example, the third epitaxial channel pattern 210 and the fourth epitaxial channel pattern 215 may each be fin-type patterns.

The first fin-type protruding pattern 220p may be located between the third epitaxial channel pattern 210 and the fourth epitaxial channel pattern 215. The spacing distance at which the third epitaxial channel pattern 210 and the fourth epitaxial channel pattern 215 may be substantially the same as the width of the first fin-type protruding pattern 220p.

In FIG. 12, the third epitaxial channel pattern 210 and the fourth epitaxial channel pattern 215 may not be in contact with the first fin-type protruding pattern 220p. That is, each of the lower surface of the third epitaxial channel pattern 210 and the lower surface of the fourth epitaxial channel pattern 215 may be higher than the upper surface of the first fin-type protruding pattern 220p.

The first fin-type protruding pattern 220p may include a different material from the third epitaxial channel pattern 210. The first fin-type protruding pattern 220p may include a semiconductor material.

The third epitaxial channel pattern 210 and the fourth epitaxial pattern 215 may each be formed on the field insulating film 105. The field insulating film 105 may be interposed between the third epitaxial channel pattern 210 and the substrate 100, and between the fourth epitaxial channel pattern 215 and the substrate 100.

Each of the upper surface of the third epitaxial channel pattern 210 and the upper surface of the fourth epitaxial channel pattern 215 may protrude upward further than the upper surface of the field insulating film 105. The field insulating film 105 may partially cover a sidewall of the third epitaxial channel pattern 210 and a sidewall of the fourth epitaxial channel pattern 215.

The field insulating film 105 may cover an upper surface of the first fin-type protruding pattern 220p. An upper surface of the first fin-type protruding pattern 220p may not protrude upward further than an upper surface of the field insulating film 105.

In the semiconductor device according to some example embodiments, a height h3 of the first mandrel channel pattern 120 may be greater than a height h4 of the third epitaxial channel pattern 210 and a height h5 of the fourth epitaxial channel pattern 215.

The height h4 of the third epitaxial channel pattern 210 may be substantially the same as the height h5 of the fourth epitaxial channel pattern 215.

The field insulating film 105 may be interposed between the third epitaxial channel pattern 210 and the substrate 100 and between the fourth epitaxial channel pattern 215 and the substrate 100, but not between the first fin-type protruding pattern 220p and the substrate 100.

A width W4 of the third epitaxial channel pattern 210 may be substantially the same as a width W5 of the fourth epitaxial channel pattern 215.

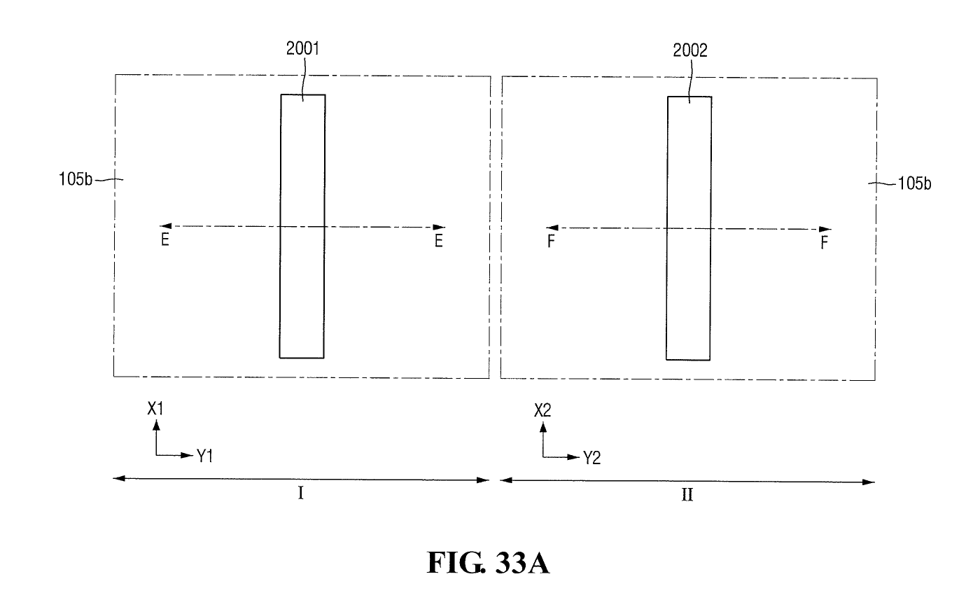

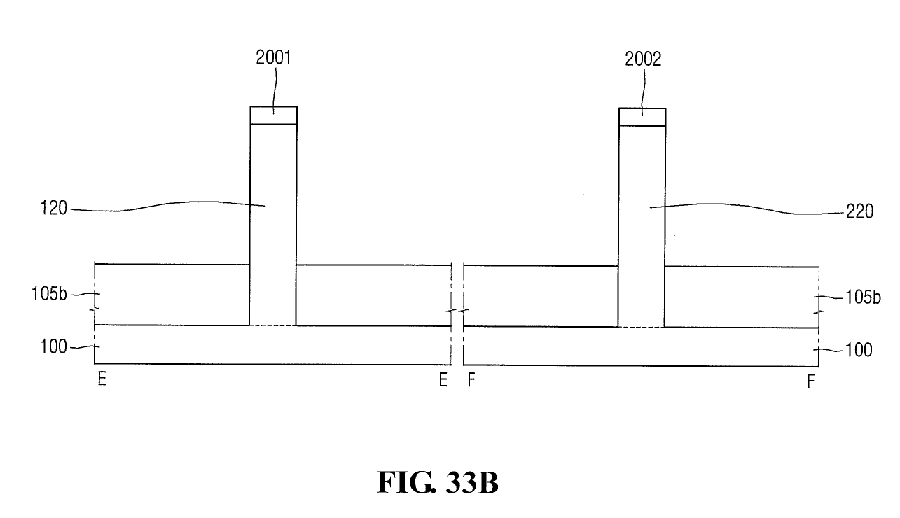

When using the fabricating methods described with reference to FIGS. 33 to 37, the width W4 of the third epitaxial channel pattern 210 may be equal to the spacing distance between the first epitaxial channel pattern 110 and the first mandrel channel pattern 120, and the width W5 of the fourth epitaxial channel pattern 215 may be equal to the spacing distance between the second epitaxial channel pattern 115 and the first mandrel channel pattern 120.

The second gate electrode 230 may extend in a fourth direction Y2. The second gate electrode 230 may be formed on the field insulating film 105 formed on the substrate 100.

The second gate electrode 230 may surround the third epitaxial channel pattern 210 and the fourth epitaxial channel pattern 215 that protrude upward further than the upper surface of the field insulating film 105.

The second gate insulating film 235 may be formed along profiles of the third epitaxial channel pattern 210 and the fourth epitaxial channel pattern 215 that protrude upward further than the field insulating film 105. A second gate insulating film 235 may be formed between the field insulating film 105 and the second gate electrode 230.

The cross sectional view taken on line A-A of FIG. 11 is illustrated similarly to FIG. 2, but not limited thereto. The cross sectional view taken on line A-A of FIG. 11 may be similar to any one of FIGS. 5 to 8. In this case, it is of course possible that the cross sectional view taken on line D-D of FIG. 11 varies depending on the cross sectional view taken on line A-A of FIG. 11.

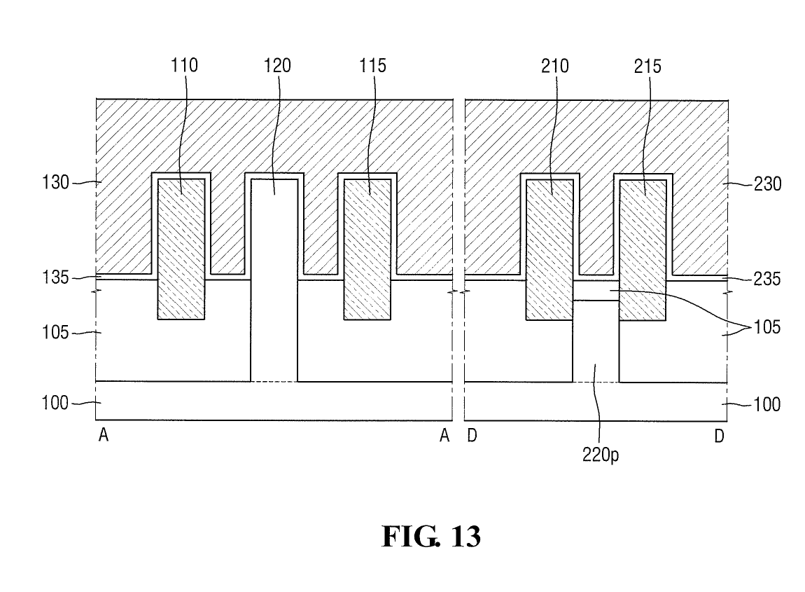

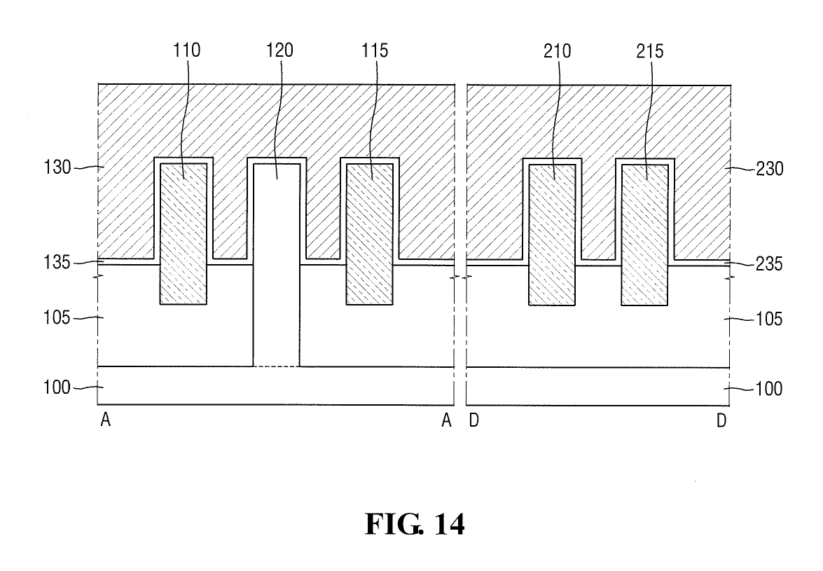

FIG. 13 is a view provided to explain a semiconductor device according to some example embodiments. FIG. 14 is a view provided to explain a semiconductor device according to some example embodiments. For convenience of explanation, differences that are not explained above with reference to FIGS. 11 and 12 will be mainly explained below.

Referring to FIG. 13, in the semiconductor device according to some example embodiments, the third epitaxial channel pattern 210 and the fourth epitaxial channel pattern 215 may be in contact with the first fin-type protruding pattern 220p.

Each of the lower surface of the third epitaxial channel pattern 210 and the lower surface of the fourth epitaxial channel pattern 215 may be lower than the upper surface of the first fin-type protruding pattern 220p.

Referring to FIG. 14, in the semiconductor device according to some example embodiments, no fin-type protruding pattern protruding from the substrate 100 is between the third epitaxial channel pattern 210 and the fourth epitaxial channel pattern 215.

In the fabrication of semiconductor device, when the mandrel pattern used to form the third epitaxial channel pattern 210 and the fourth epitaxial channel pattern 215 is all removed, there may not be a first fin-type protruding pattern (220p in FIG. 12).

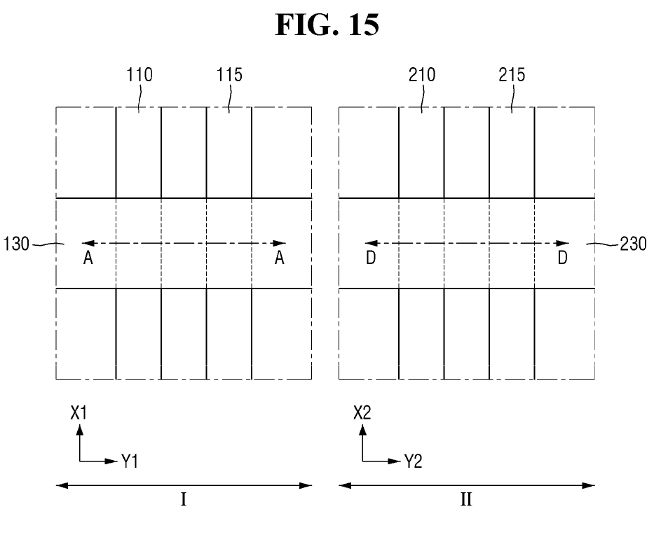

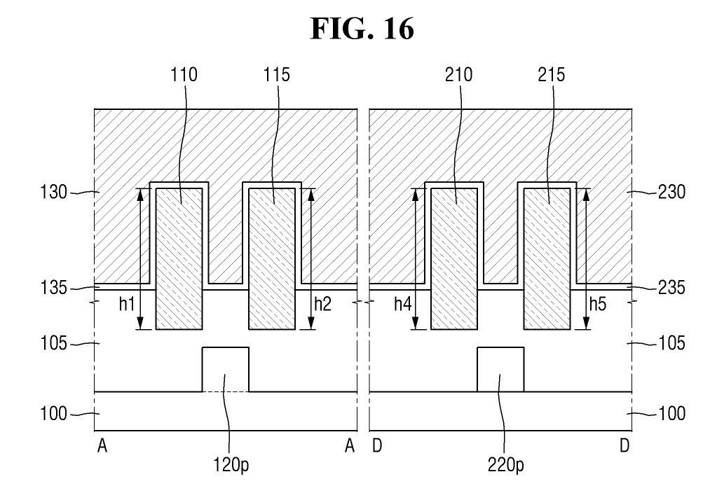

FIG. 15 is a schematic top view provided to explain a semiconductor device according to some embodiments of the present disclosure. FIG. 16 is a cross sectional view taken on lines A-A and D-D of FIG. 15. For convenience of explanation, differences that are not explained above with reference to FIGS. 11 and 12 will be mainly explained below.

Referring to FIGS. 15 and 16, a semiconductor device according to some embodiments may include a first epitaxial channel pattern 110, a second epitaxial channel pattern 115, a third epitaxial channel pattern 210, a fourth epitaxial channel pattern 215, a first gate electrode 130, a second gate electrode 230, a first fin-type protruding pattern 220p, and a second fin-type protruding pattern 120p.

The first epitaxial channel pattern 110, the second epitaxial channel pattern 115, the second fin-type protruding pattern 120p, and the first gate electrode 130 may be formed in the first region I.

The third epitaxial channel pattern 210, the fourth epitaxial channel pattern 215, the first fin-type protruding pattern 220p, and the second gate electrode 230 may be formed in the second region II.

Each of the first epitaxial channel pattern 110 and the second epitaxial channel pattern 115 may spatially be spaced apart from the substrate 100.

The second fin-type protruding pattern 120p may be located between the first epitaxial channel pattern 110 and the second epitaxial channel pattern 115. The spacing distance between the first epitaxial channel pattern 110 and the second epitaxial channel pattern 115 may be substantially the same as a width of the second fin-type protruding pattern 120p.

The first epitaxial channel pattern 110 and the second epitaxial channel pattern 115 may not be in contact with the second fin-type protruding pattern 120p. Each of the lower surface of the first epitaxial channel pattern 110 and the lower surface of the second epitaxial channel pattern 115 may be higher than the upper surface of the second fin-type protruding pattern 120p.

The second fin-type protruding pattern 120p may include a different material from the first epitaxial channel pattern 110.

Further, the first fin-type protruding pattern 220p may include a different material from the third epitaxial channel pattern 210 and the substrate 100. The first fin-type protruding pattern 220p may include a different material from the second fin-type protruding pattern 120p.

The field insulating film 105 may cover the upper surface of the first fin-type protruding pattern 220p and the upper surface of the second fin-type protruding pattern 120p. The upper surface of the first fin-type protruding pattern 220p and the upper surface of the second fin-type protruding pattern 120p may not protrude upward further than the upper surface of the field insulating film 105.

A height h1 of the first epitaxial channel pattern 110 may be the same as a height h2 of the second epitaxial channel pattern 115, and a height h4 of the third epitaxial channel pattern 210 may be the same as a height h5 of the fourth epitaxial channel pattern 215.

As illustrated in FIG. 16, the first epitaxial channel pattern 110 may not be in contact with the second fin-type protruding pattern 120p, and the third epitaxial channel pattern 210 may not be in contact with the first fin-type protruding pattern 220p, although example embodiments are not limited thereto.

The first epitaxial channel pattern 110 may be in contact with the second fin-type protruding pattern 120p, or the third epitaxial channel pattern 210 may be in contact with the first fin-type protruding pattern 220p.

In some embodiments, similar to descriptions with reference to FIG. 14, the first fin-type protruding pattern 220p and the second fin-type protruding pattern 120p may not be formed.

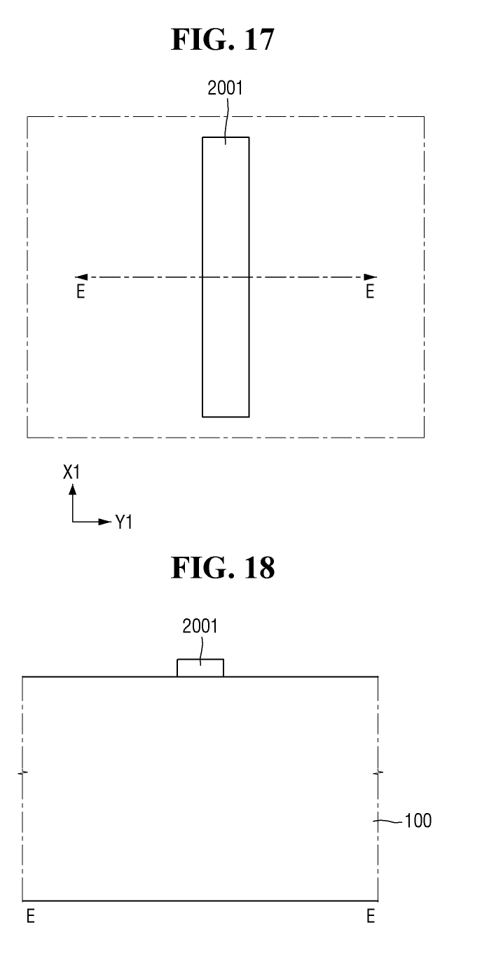

FIGS. 17 to 26 are views illustrating intermediate stages of fabrication, provided to explain methods for fabricating a semiconductor device according to some example embodiments. FIG. 18 is a cross sectional view taken on line E-E of FIG. 17.

Referring to FIGS. 17 and 18, a first hard mask pattern 2001 may be formed on the substrate 100 and extend in the first direction X1.

For example, the first hard mask pattern 2001 may include at least one of silicon nitride, silicon oxynitride, silicon oxide, and/or a combination thereof.

In describing methods for fabricating a semiconductor device according to some example embodiments, it is assumed that the substrate 100 is a silicon substrate.

An example embodiment will now be described with reference to FIG. 18 that is a cross sectional view.

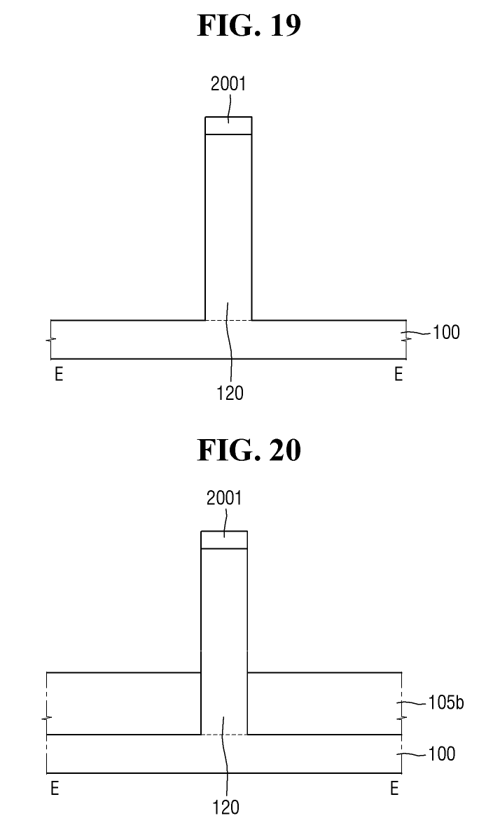

Referring to FIG. 19, a first mandrel channel pattern 120 may be formed on the substrate 100 using the first hard mask pattern 2001.

A portion of the substrate 100 may be removed by using the first hard mask pattern 2001 as an etch mask. As a result, the first mandrel channel pattern 120 is formed, protruding from the substrate 100, and elongated in the first direction X1. The first mandrel channel pattern 120 may have a shape of a fin-type pattern.

The first mandrel channel pattern 120 formed by etching a portion of the substrate 100 may be a silicon fin-type pattern, for example. Some embodiments provide that when epitaxial layer having a different material from the substrate 100 is formed on the substrate 100, then the first mandrel channel pattern 120 may include a material included in the epitaxial layer.

Referring to FIG. 20, a lower field insulating film 105b is formed on the substrate 100. The lower field insulating film 105b partially covers a sidewall of the first mandrel channel pattern 120.

A portion of the first mandrel channel pattern 120 and the first hard mask pattern 2001 may protrude upward further than the upper surface of the lower field insulating film 105b.

The lower field insulating film 105b may include, for example, one of oxide film, nitride film, oxynitride film, and/or a combination thereof.

For example, a pre-lower field insulating film covering the first mandrel channel pattern 120 and the first hard mask pattern 2001 is formed on the substrate 100. A portion of the pre-lower field insulating film may be removed to expose a portion of the first mandrel channel pattern 120 and the first hard mask pattern 2001. As a result, a lower field insulating film 105b is formed on the substrate 100.

The first hard mask pattern 2001 may be left on the upper surface of the first mandrel channel pattern 120.

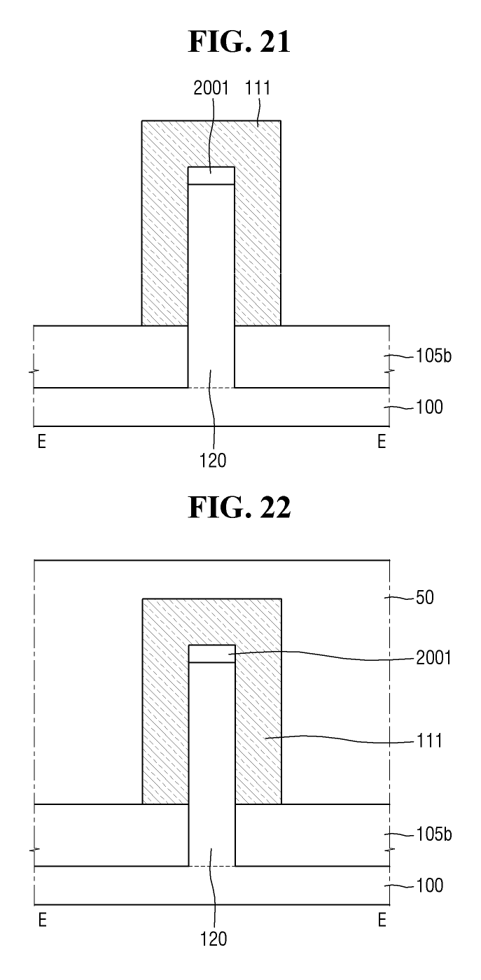

Referring to FIG. 21, a first semiconductor film 111 is formed on the lower field insulating film 105b. The first semiconductor film 111 extends along a sidewall of the first mandrel channel pattern 120 and the hard mask pattern 2001 protruding upward further than the upper surface of the lower field insulating film 105b.

The first semiconductor film 111 is formed on a sidewall of the first mandrel channel pattern 120, and formed along a profile of the first hard mask pattern 2001. That is, the first semiconductor film 111 may be formed along a profile of the first mandrel channel pattern 120 and the hard mask pattern 2001 protruding upward further than the upper surface of the lower field insulating film 105b.

The first semiconductor film 111 may be formed by using the epitaxial process, for example. In methods for fabricating a semiconductor device according to some example embodiments, the first semiconductor film 111 may include a semiconductor material having etch selectivity to the first mandrel channel pattern 120, such as include silicon germanium, for example.

It is of course possible that the first semiconductor film 111 includes other material depending on a material of the first mandrel channel pattern 120.

As illustrated in FIG. 21, the first semiconductor film 111 has no facet grown between the first semiconductor film 111 and the upper surface of the lower field insulating film 105b. However, this is illustrated so only for convenience of explanation and the example embodiments are not limited thereto. It is of course possible that the first semiconductor film 111 may include a facet between the first semiconductor film 111 and the upper surface of the lower field insulating film 105b.

The first semiconductor film 111 may be formed on the first hard mask pattern 2001 that is an insulating material, but not formed along the upper surface of the lower field insulating film 105b that is the insulating material. That is, although the first hard mask pattern 2001 and the lower field insulating film 105b are the insulating materials, the first semiconductor film 111 may be formed on the first hard mask pattern 2001, but not formed on the upper surface of the lower field insulating film 105b.

The reason for such difference may be explained as below, for example.

For example, the lower field insulating film 105b may include oxide, and the first hard mask pattern 2001 may include nitride. Due to difference of insulating materials, the first semiconductor film 111 may be formed on the first hard mask pattern 2001, but not formed on the upper surface of the lower field insulating film 105b.

In some embodiments, a dimension of the first hard mask pattern 2001 is less than a dimension of the lower field insulating film 105b. That is, due to difference of the dimensions, the first semiconductor film 111 may be formed on the first hard mask pattern 2001, but not formed on the upper surface of the lower field insulating film 105b.

Above explains some of the example reasons that can cause variations in the growth of the first semiconductor film 111, but of course the present disclosure is not limited thereto.

Referring to FIG. 22, a support insulating film 50 covering the first semiconductor film 111 is formed on the lower field insulating film 105b.

The support insulating film 50 may be a sacrificial insulating film for forming the first and second epitaxial channel patterns 110 and 115 formed later, and may be a portion of the field insulating film 105 (FIG. 25).

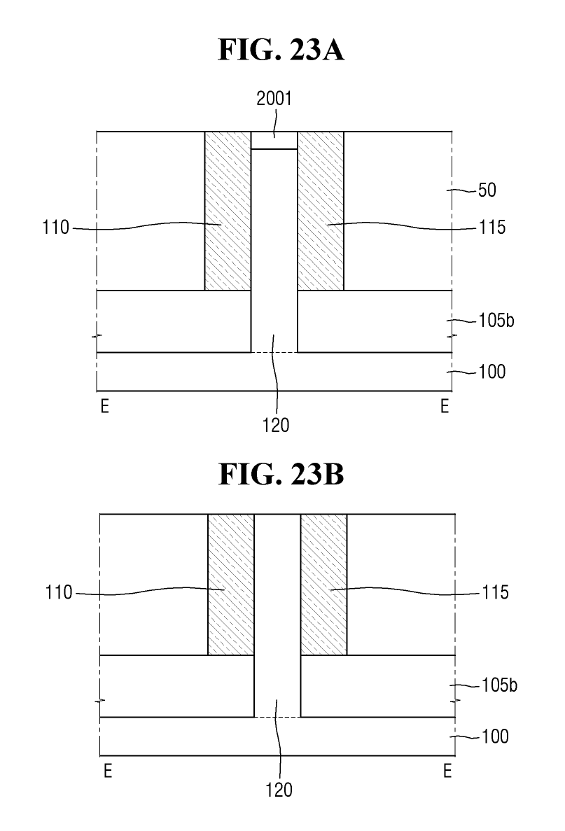

Referring to FIGS. 23A and 23B, the upper surface of the first mandrel channel pattern 120 may be exposed to form the first epitaxial channel pattern 110 and the second epitaxial channel pattern 115 on a sidewall of the first mandrel channel pattern 120.

In FIG. 23A, the support insulating film 50 may be partially removed to be planarized by using the first hard mask pattern 2001 as an etch stop film.

With the planarization of the support insulating film 50, at least a portion of the first semiconductor film 111 formed along the first hard mask pattern 2001 may be removed. Further, the first mask pattern 2001 may be exposed.

Referring to FIG. 23B, the first hard mask pattern 2001 may be removed to expose the upper surface of the first mandrel channel pattern 120. During removal of the first hard mask pattern 2001, a portion of the first epitaxial channel pattern 110, a portion of the second epitaxial channel pattern 115, and a portion of the support insulating film 50 may also be removed.

As a result, the upper surface of the first mandrel channel pattern 120, the upper surface of the first epitaxial channel pattern 110, and the upper surface of the second epitaxial channel pattern 115 may be placed on the same plane. That is, the height from the substrate 100 to the upper surface of the first epitaxial channel pattern 110 and the height from the substrate 100 to the upper surface of the second epitaxial channel pattern 115 may be substantially equal to the height from the substrate 100 to the upper surface of the first mandrel channel pattern 120.

Unlike the embodiment described above, in the condition as illustrated in FIG. 23A, the first hard mask pattern 2001 may be removed without removing a portion of the first epitaxial channel pattern 110 and a portion of the second epitaxial channel pattern 115, or without removing a portion of the first epitaxial channel pattern 110 and the second epitaxial channel pattern 115 by a thickness of the first hard mask pattern 2001.

In this case, the upper surface of the first epitaxial channel pattern 110 and the upper surface of the second epitaxial channel pattern 115 may be higher than the upper surface of the first mandrel channel pattern 120. That is, the height from the substrate 100 to the upper surface of the first epitaxial channel pattern 110 and the height from the substrate 100 to the upper surface of the second epitaxial channel pattern 115 may be substantially higher than the height from the substrate 100 to the upper surface of the first mandrel channel pattern 120.

An example embodiment will now be described with reference to FIG. 23B.

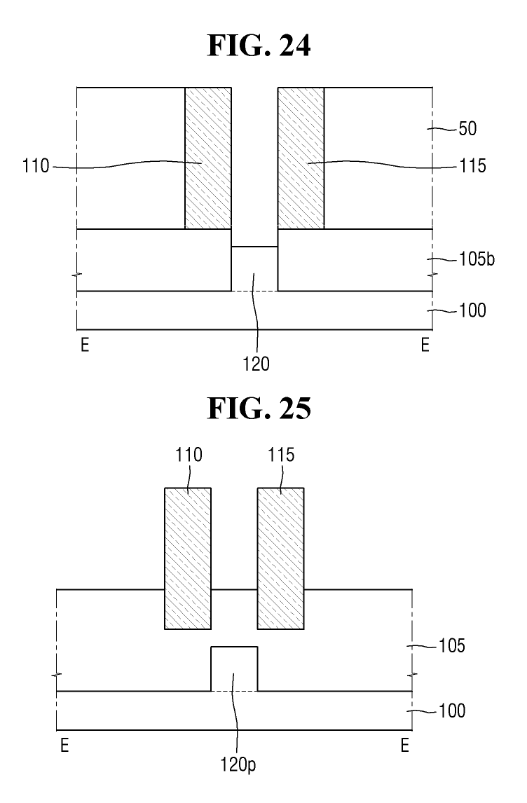

Referring to FIG. 24, the first mandrel channel pattern 120 may be partially removed to form a second fin-type protruding pattern 120p on the substrate 100.

A portion of the first mandrel channel pattern 120 may be removed using etch selectivity with the first epitaxial channel pattern 110 and the second epitaxial channel pattern 115.

As illustrated in FIG. 24, the second fin-type protruding pattern 120p may not be in contact with the first epitaxial channel pattern 110 and the second epitaxial channel pattern 115, but not limited thereto.

Further, the first mandrel channel pattern 120 may be entirely removed such that the second fin-type protruding pattern 120p may not be formed.

Referring FIG. 25, a field insulating film 105 may be formed on the substrate 100 so as to partially cover a sidewall of the first epitaxial channel pattern 110 and a sidewall of the second epitaxial channel pattern 115. The field insulating film 105 may cover an upper surface of the second fin-type protruding pattern 120p.

The field insulating film 105 may include the lower field insulating film 105b, and additional insulating film on the lower field insulating film 105b.

As illustrated in FIG. 25, the field insulating film 105 may partially cover a sidewall of the first epitaxial channel pattern 110 and a sidewall of the second epitaxial channel pattern 115, but not limited thereto. It is of course possible that a field insulating film 105 may not cover a sidewall of the first epitaxial channel pattern 110 and a sidewall of the second epitaxial channel pattern 115.

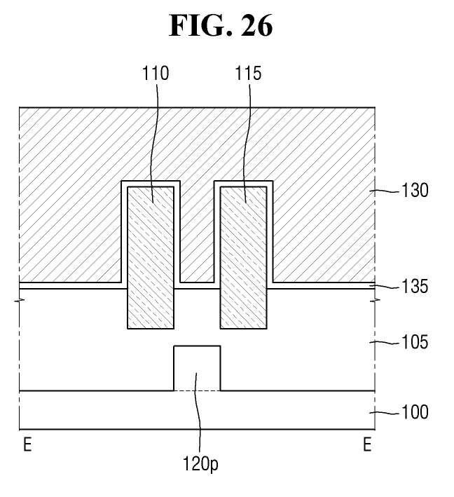

Referring to FIG. 26, the first gate insulating film 135 is formed along the first epitaxial channel pattern 110 and the second epitaxial channel pattern 115 and the upper surface of the field insulating film 105 protruding upward further than the upper surface of the field insulating film 105.

The first gate insulating film 135 is formed on the field insulating film 105, the first epitaxial channel pattern 110 and the second epitaxial channel pattern 115.

The first gate electrode 130 intersecting the first epitaxial channel pattern 110 and the second epitaxial channel pattern 115 is formed on the first gate insulating film 135.

Before the first gate insulating film 135 is formed, the first epitaxial channel pattern 110 and the second epitaxial channel pattern 115 may be spaced apart from the upper surface of the field insulating film 105, and have a similar shape to a wire pattern, when a portion of the field insulating film 105 is removed.

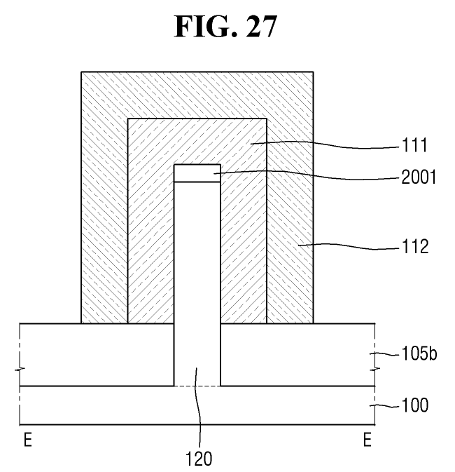

FIGS. 27 to 30 are views illustrating intermediate stages of fabrication, provided to explain methods for fabricating a semiconductor device according to some example embodiments. FIG. 27 may involve a process performed after FIG. 21.

Referring to FIG. 27, a second semiconductor film 112 is formed on the first semiconductor film 111.

The second semiconductor film 112 may be formed along a profile of the first semiconductor film 111. The second semiconductor film 112 is formed on a sidewall of the first mandrel channel pattern 120, and formed along a profile of the first hard mask pattern 2001.

The second semiconductor film 112 may be formed by using the epitaxial process, for example. In methods for fabricating a semiconductor device according to some example embodiments, the second semiconductor film 112 may include a semiconductor material having etch selectivity to the first semiconductor film 111. Further, the second semiconductor film 112 may include a semiconductor material same as the first mandrel channel pattern 120, for example.

The first semiconductor film 111 and the second semiconductor film 112 may be formed in a subsequent order along a profile of the first mandrel channel pattern 120 and the hard mask pattern 2001 protruding upward further than the upper surface of the lower field insulating film 105b.

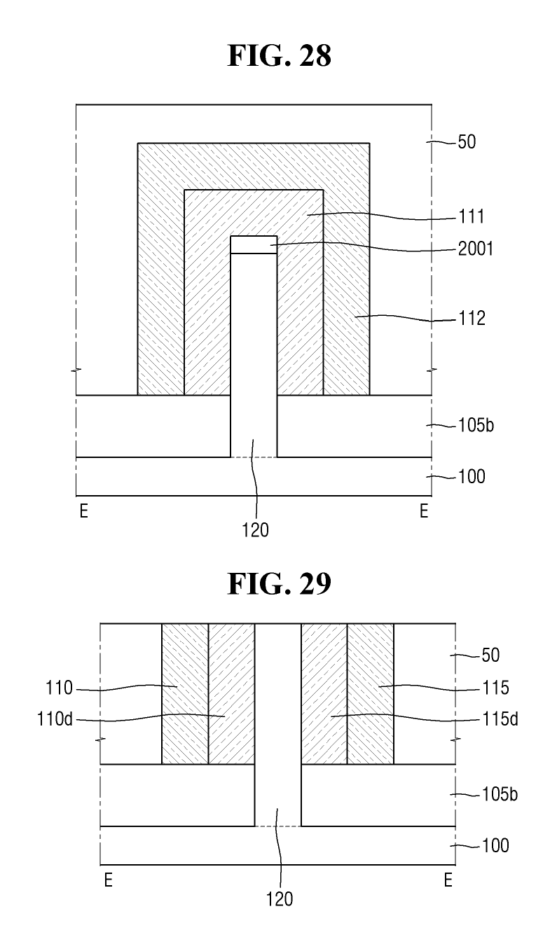

Referring to FIG. 28, a support insulating film 50 covering the second semiconductor film 112 is formed on the lower field insulating film 105b.

Referring to FIG. 29, a portion of the support insulating film 50 may be removed to expose the upper surface of the mandrel channel pattern 120.

A first sacrificial epitaxial channel pattern 110d and a second sacrificial epitaxial channel pattern 115d may be formed on a sidewall of the first mandrel channel pattern 120. The first epitaxial channel pattern 110 and the second epitaxial channel pattern 115 may be formed on the first sacrificial epitaxial channel pattern 110d and the second sacrificial epitaxial channel pattern 115d.

That is, the first sacrificial epitaxial channel pattern 110d and the first epitaxial channel pattern 110 may be sequentially formed on one sidewall of the first mandrel channel pattern 120. The second sacrificial epitaxial channel pattern 115d and the second epitaxial channel pattern 115 may be sequentially formed on the other sidewall of the first mandrel channel pattern 120.

At least a portion of the first semiconductor film 111 formed along the first hard mask pattern 2001 is removed to form the first sacrificial epitaxial channel pattern 110d and the second sacrificial epitaxial channel pattern 115d.

Further, at least a portion of the second semiconductor film 112 formed along the first hard mask pattern 2001 is removed to form the first epitaxial channel pattern 110 and the second epitaxial channel pattern 115.

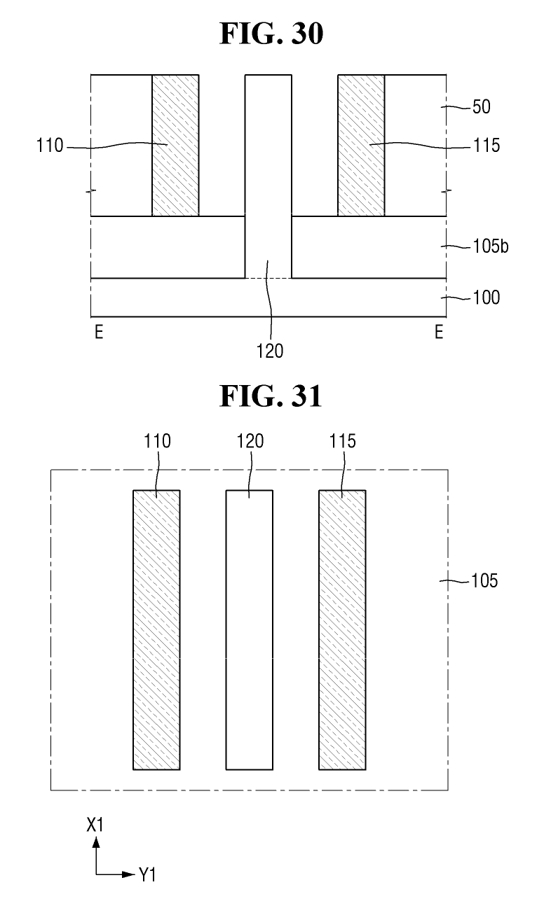

Referring to FIG. 30, the first sacrificial epitaxial channel pattern 110d and the second sacrificial epitaxial channel pattern 115d may be removed.

The first sacrificial epitaxial channel pattern 110d may be removed to form space between the first mandrel channel pattern 120 and the first epitaxial channel pattern 110. Further, the second sacrificial epitaxial channel pattern 115d may be removed to form space between the first mandrel channel pattern 120 and the second epitaxial channel pattern 115.

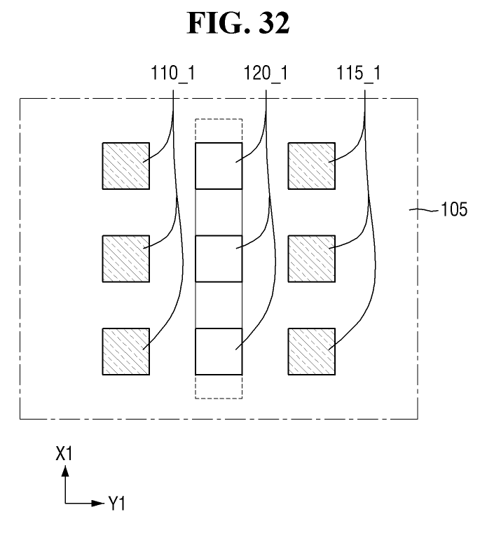

FIGS. 31 and 32 are views illustrating intermediate stages of fabrication, provided to explain methods for fabricating a semiconductor device according to some example embodiments. FIG. 31 may be a top view illustrating a process performed after FIG. 30.

Referring FIG. 31, the field insulating film 105 may be formed so as to partially cover a sidewall of the first mandrel channel pattern 120, a sidewall of the first epitaxial channel pattern 110, and a sidewall of the second epitaxial channel pattern 115.

Referring to FIG. 32, the first mandrel channel pattern 120, the first epitaxial channel pattern 120, and the second epitaxial channel pattern 115, which protrude upward further than the field insulating film 105, may be patterned.

As a result, a plurality of first vertical mandrel channel patterns 120_1, a plurality of first vertical epitaxial channel patterns 110_1, and a plurality of second vertical epitaxial channel patterns 115_1 may be formed on the field insulating film 105.

Then, like FIG. 10, a vertical transistor may be fabricated using a plurality of first vertical mandrel channel patterns 120_1, a plurality of first vertical epitaxial channel patterns 110_1, and a plurality of second vertical epitaxial channel patterns 115_1.

FIGS. 33A to 37 are views illustrating intermediate stages of fabrication, provided to explain a method for fabricating a semiconductor device according to some example embodiments. FIG. 33B are sectional views taken along lines E-E and F-F of FIG. 33A.

For reference, the first region I in FIGS. 33A and 33B will be described briefly, since some of the description would overlap with the description provided above with reference to FIGS. 17 to 20.

Referring to FIGS. 33A and 33B, a first mandrel channel pattern 120 may be formed on the substrate 100 in the first region I using the first hard mask pattern 2001. The second mandrel channel pattern 220 may be formed on the substrate 100 in the second region II using the second hard mask pattern 2002.

The first mandrel channel pattern 120 may be elongated in the first direction X1, and the second mandrel channel pattern 220 may be elongated in the third direction X2.

The first mandrel channel pattern 120 and the second mandrel channel pattern 220 may include the same material as each other.

Then, a lower field insulating film 105b is formed on the substrate 100. The lower field insulating film 105b may partially cover the sidewall of the first mandrel channel pattern 120 and the sidewall of the second mandrel channel pattern 220.

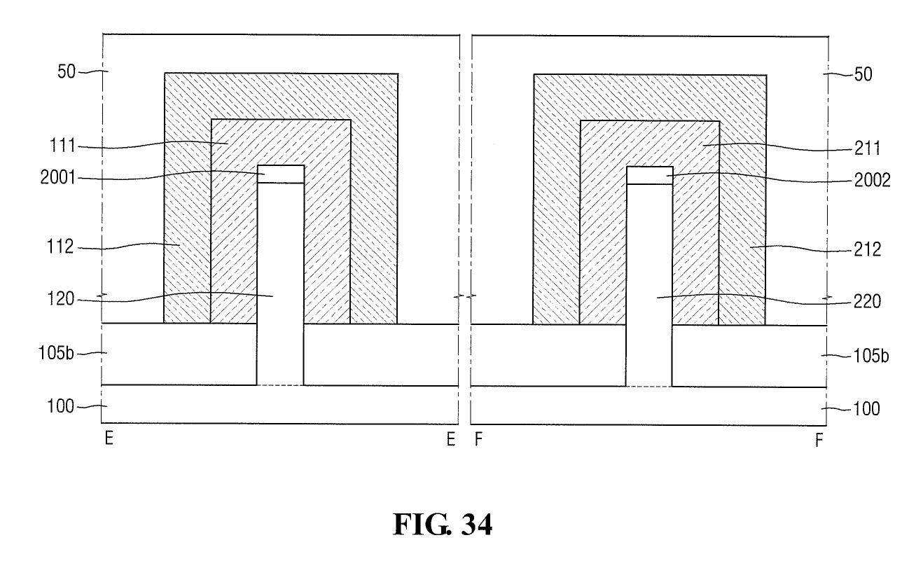

Referring to FIG. 34, the first semiconductor film 111 and the third semiconductor film 211 are formed on the lower field insulating film 105b.

The third semiconductor film 211 extends along a sidewall of the second mandrel channel pattern 220 and the second hard mask pattern 2002 protruding upward further than the upper surface of the lower field insulating film 105b.

The third semiconductor film 211 is formed on a sidewall of the second mandrel channel pattern 220, and formed along a profile of the second hard mask pattern 2002.

The first semiconductor film 111 and the third semiconductor film 211 may be formed by using the epitaxial process, for example. The first semiconductor film 111 and the third semiconductor film 211 may include the same material as each other.

Next, the second semiconductor film 112 is formed on the first semiconductor film 111. Further, a fourth semiconductor film 212 is formed on the third semiconductor film 211.

The fourth semiconductor film 212 may be formed along a profile of the first semiconductor film 111. The fourth semiconductor film 212 is formed on a sidewall of the second mandrel channel pattern 220, and formed along a profile of the second hard mask pattern 2002.

The second semiconductor film 112 and the fourth semiconductor film 212 may be formed by using the epitaxial process, for example. The second semiconductor film 112 and the fourth semiconductor film 212 may include the same material as each other. The fourth semiconductor film 212 may include a semiconductor material same as the second mandrel channel pattern 220, for example.

Next, a support insulating film 50 covering the second semiconductor film 112 and the fourth semiconductor film 212 is formed on the lower field insulating film 105b.

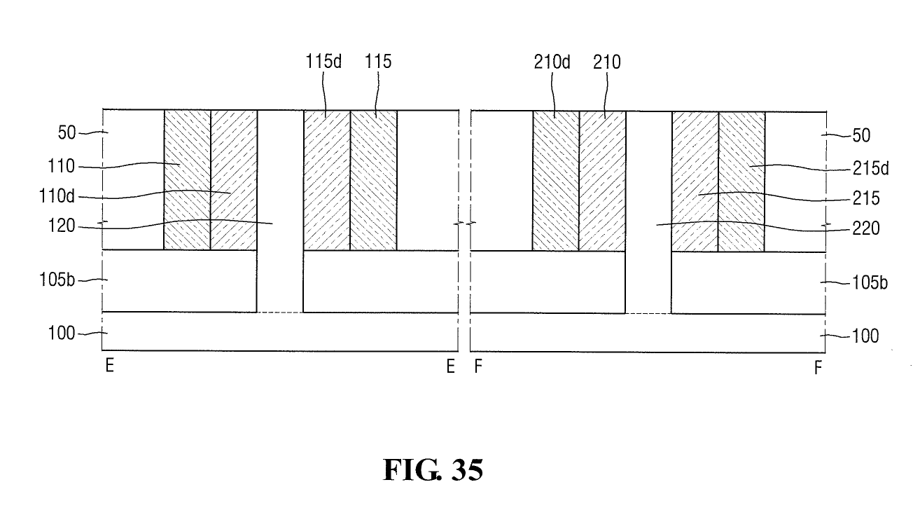

Referring to FIG. 35, a portion of the support insulating film 50 may be removed to expose the upper surface of the first mandrel channel pattern 120 and the upper surface of the second mandrel channel pattern 220.

The third epitaxial channel pattern 210 and the fourth epitaxial channel pattern 215 may be formed on a sidewall of the second mandrel channel pattern 220. The third sacrificial channel pattern 210d and the fourth sacrificial channel pattern 215d may be formed on the third epitaxial channel pattern 210 and the fourth epitaxial channel pattern 215.

That is, the third epitaxial channel pattern 210 and the third sacrificial epitaxial channel pattern 210d may be sequentially formed on one sidewall of the second mandrel channel pattern 220. The fourth epitaxial channel pattern 215 and the fourth sacrificial epitaxial channel pattern 215d may be sequentially formed on the other sidewall of the second mandrel channel pattern 220.

At least a portion of the third semiconductor film 211 formed along the second hard mask pattern 2002 is removed to form the third epitaxial channel pattern 210 and the fourth epitaxial channel pattern 215.

Further, at least a portion of the fourth semiconductor film 212 formed along the second hard mask pattern 2002 is removed to form the third sacrificial epitaxial channel pattern 210d and the fourth sacrificial epitaxial channel pattern 215d.

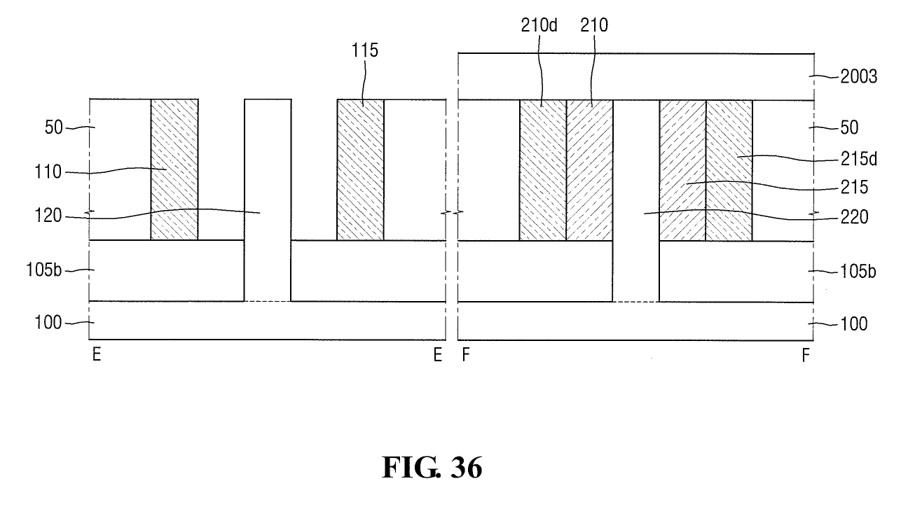

Referring FIG. 36, the first mask pattern 2003 may be formed on the second mandrel channel pattern 220, the third epitaxial channel pattern 210, and the fourth epitaxial channel pattern 215.

The first sacrificial epitaxial channel pattern 110d and the second sacrificial epitaxial channel pattern 115d may be removed using the first mask pattern 2003.

Next, the first mask pattern 2003 may be removed.

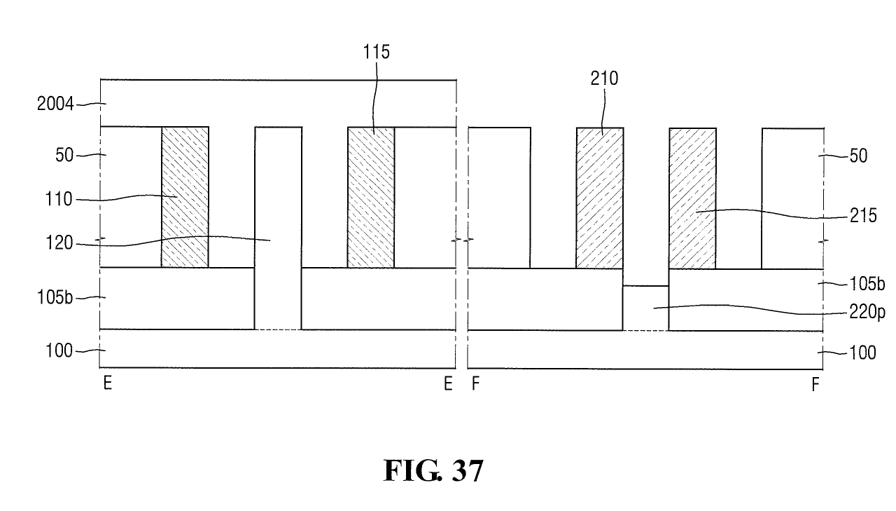

Referring FIG. 37, the second mask pattern 2004 may be formed on the first mandrel channel pattern 120, the first epitaxial channel pattern 110, and the second epitaxial channel pattern 115.

A portion of the second mandrel channel pattern 220, the third sacrificial epitaxial channel pattern 210d and the fourth sacrificial epitaxial channel pattern 215d may be removed using the second mask pattern 2004.

The first fin-type protruding pattern 220p may be formed between the third epitaxial channel pattern 210 and the fourth epitaxial channel pattern 215, but not limited thereto.

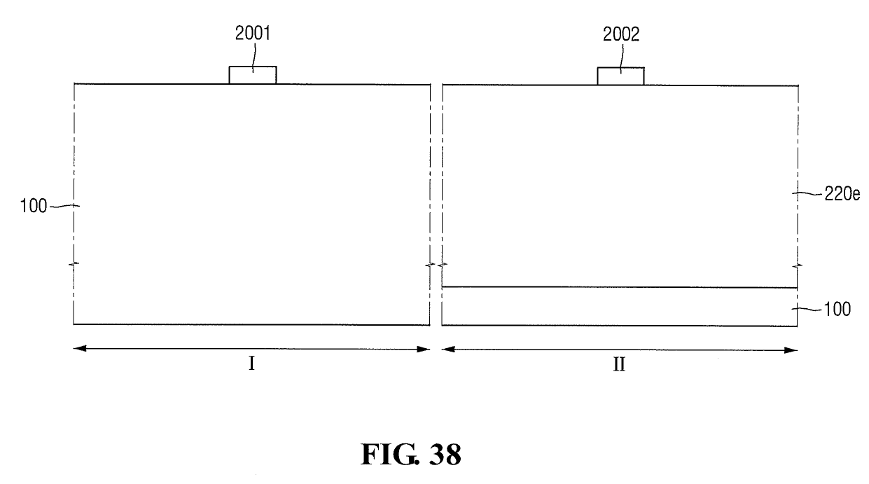

FIGS. 38 to 43 are views illustrating intermediate stages of fabrication, provided to explain methods for fabricating a semiconductor device according to some example embodiments.

Referring FIG. 38, the epitaxial film 220e is formed on the substrate 100 in the second region II.

The epitaxial film 220e may be formed by using the epitaxial process, for example. The epitaxial film 220e may include a different semiconductor material from the substrate 100.

The epitaxial film 220e may be formed after removing a portion of the substrate 100 in the second region II, but not limited thereto.

Next, the first hard mask pattern 2001 may be formed on the substrate 100 in the first region I, and the second hard mask pattern 2002 may be formed on the epitaxial film 220e in the second region II.

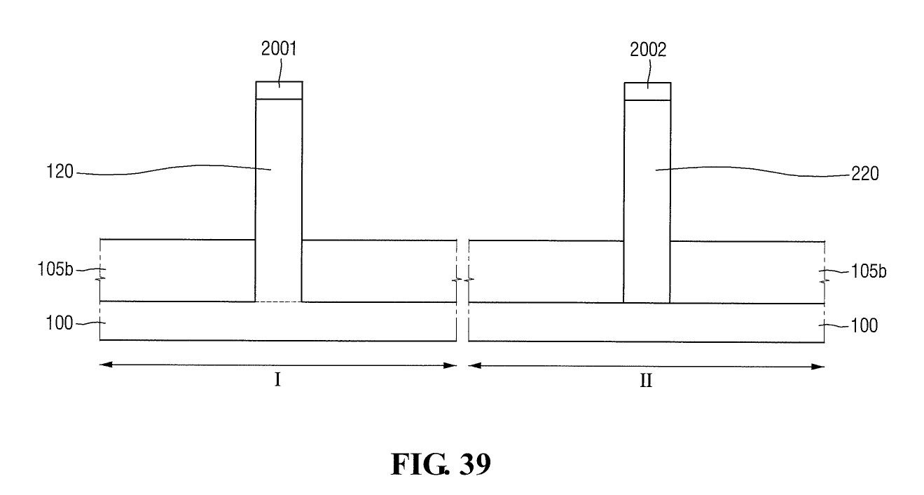

Referring to FIG. 39, a first mandrel channel pattern 120 may be formed in the first region I using the first hard mask pattern 2001, and a second mandrel channel pattern 220 may be formed in the second region II using the second hard mask pattern 2002.

The first mandrel channel pattern 120 may be formed by patterning the substrate 100, and the second mandrel channel pattern 220 may be formed by patterning the epitaxial film 220e.

The first mandrel channel pattern 120 and the second mandrel channel pattern 220 may include a different material from each other.

Then, a lower field insulating film 105b is formed on the substrate 100.

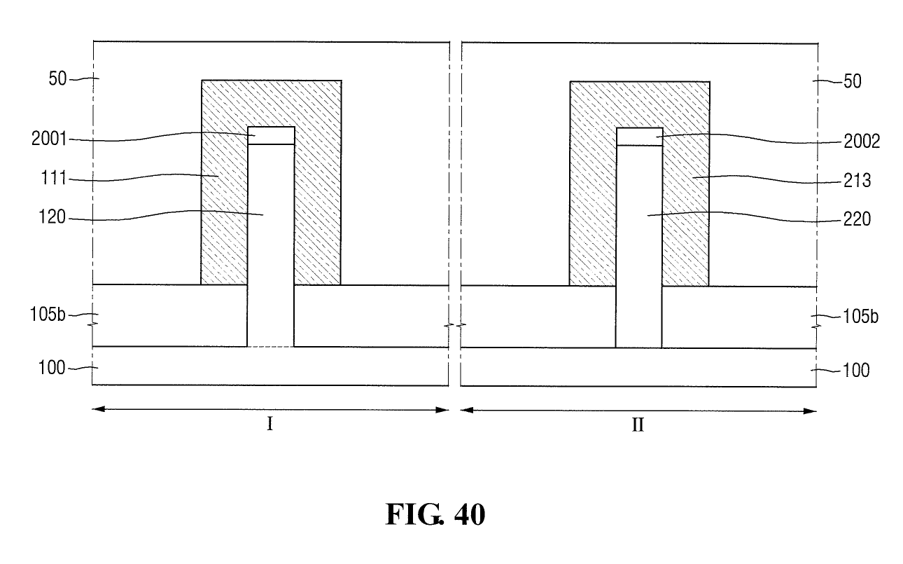

Referring to FIG. 40, a first semiconductor film 111 is formed on the lower field insulating film 105b. The first semiconductor film 111 extends along a sidewall of the first mandrel channel pattern 120 and the hard mask pattern 2001 protruding upward further than the upper surface of the lower field insulating film 105b.

The first semiconductor film 111 may include a semiconductor material having an etch selectivity to the first mandrel channel pattern 120 When the first mandrel channel pattern 120 is a silicon pattern, the first semiconductor film 111 may be a silicon germanium, for example, but not limited thereto.

Further, a fifth semiconductor film 213 is formed the lower field insulating film 105b. The fifth semiconductor film 213 extends along a sidewall of the second mandrel channel pattern 220 and the second hard mask pattern 2002 protruding upward further than the upper surface of the lower field insulating film 105b.

The fifth semiconductor film 213 may include a semiconductor material having an etch selectivity to the second mandrel channel pattern 220 When the second mandrel channel pattern 220 is a silicon germanium pattern, the fifth semiconductor film 213 may be silicon film, for example, but not limited thereto.

Next, a support insulating film 50 covering the first semiconductor film 111 and the fifth semiconductor film 213 is formed on the lower field insulating film 105b.

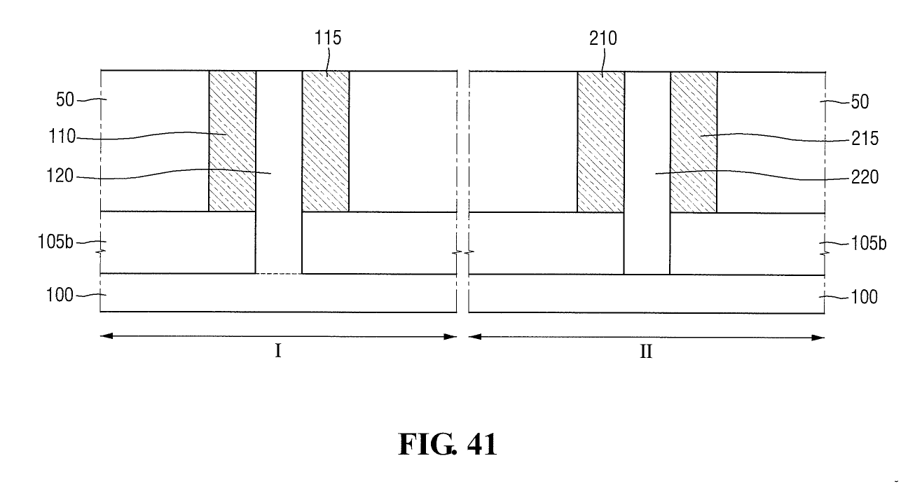

Referring to FIG. 41, a portion of the support insulating film 50 may be removed to expose the upper surface of the first mandrel channel pattern 120 and the upper surface of the second mandrel channel pattern 220.

At least a portion of the first semiconductor film 111 formed along the first hard mask pattern 2001 is removed so as to form the first epitaxial channel pattern 110 and the second epitaxial channel pattern 115 on the sidewall of the first mandrel channel pattern 120.

At least a portion of the fifth semiconductor film 213 formed along the second hard mask pattern 2002 is removed so as to form the third epitaxial channel pattern 210 and the fourth epitaxial channel pattern 215 on the sidewall of the second mandrel channel pattern 220.

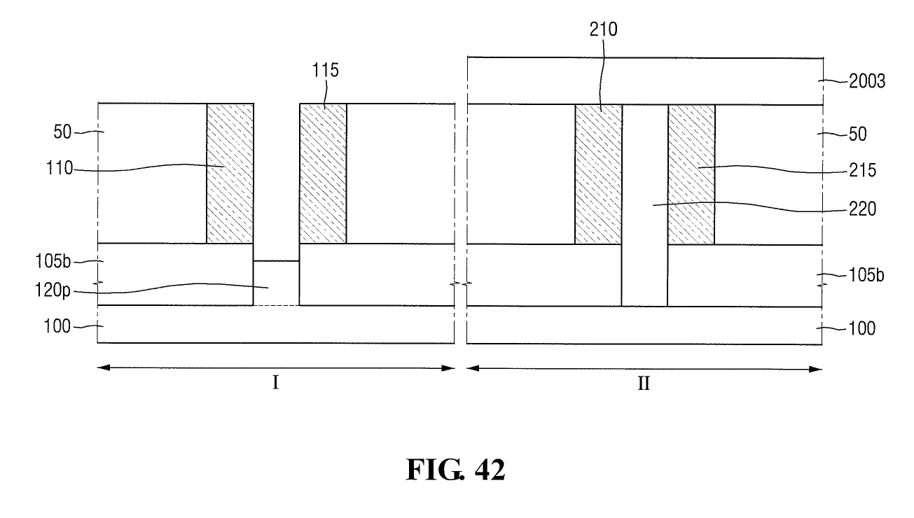

Referring to FIG. 42, the first mask pattern 2003 may be formed on the second mandrel channel pattern 220, the third epitaxial channel pattern 210, and the fourth epitaxial channel pattern 215.

At least of a portion of the first mandrel channel pattern 120 may be removed using the first mask pattern 2003.

The second fin-type protruding pattern 120p may be formed between the first epitaxial channel pattern 110 and the second epitaxial channel pattern 115, but not limited thereto.

Next, the first mask pattern 2003 may be removed.

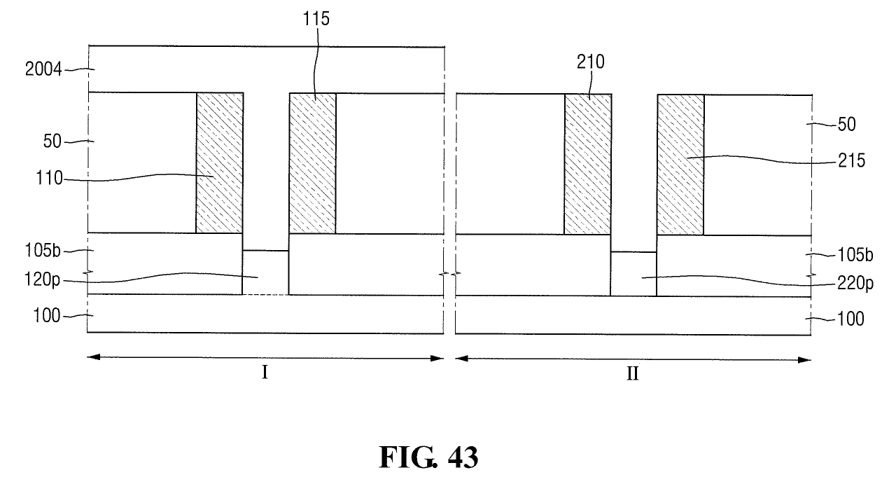

Referring to FIG. 43, the second mask pattern 2004 may be formed on the first epitaxial channel pattern 110, and the second epitaxial channel pattern 115.

At least a portion of the second mandrel channel pattern 220 may be removed using the second mask pattern 2004.

The first fin-type protruding pattern 220p may be formed between the third epitaxial channel pattern 210 and the fourth epitaxial channel pattern 215, but not limited thereto.

In concluding the detailed description, those skilled in the art will appreciate that many variations and modifications can be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor device, comprising:
a first multi-channel active pattern protruding from a substrate, and having a first height;
a second multi-channel active pattern on the substrate, being spaced apart from the substrate, and having a second height that is less than the first height; and
a gate electrode on the substrate, intersecting the first multi-channel active pattern and the second multi-channel active pattern.

2. The semiconductor device of claim 1, wherein a height from the substrate to an uppermost portion of the first multi-channel active pattern is equal to or less than a height from the substrate to an uppermost portion of the second multi-channel active pattern.

3. The semiconductor device of claim 1, further comprising a field insulating film on the substrate,
wherein the field insulating film is interposed between the substrate and the second multi-channel active pattern.

4. The semiconductor device of claim 3, wherein the field insulating film covers a portion of a sidewall of the first multi-channel active pattern and a portion of a sidewall of the second multi-channel active pattern.

5. The semiconductor device of claim 3, wherein the field insulating film is not interposed between the first multi-channel active pattern and the substrate.

6. The semiconductor device of claim 1, further comprising a third multi-channel active pattern on the substrate, being spaced apart from the substrate, and having a third height that is less than the first height,
wherein the first multi-channel active pattern is located between the second multi-channel active pattern and the third multi-channel active pattern.

7. The semiconductor device of claim 6, wherein a height from the substrate to an uppermost portion of the first multi-channel active pattern is equal to or less than a height from the substrate to an uppermost portion of the third multi-channel active pattern.

8. The semiconductor device of claim 6, wherein a distance between the first multi-channel active pattern and the second multi-channel active pattern is substantially equal to a distance between the first multi-channel active pattern and the third multi-channel active pattern.

9. The semiconductor device of claim 1, wherein the substrate includes a first region and a second region,
the first multi-channel active pattern and the second multi-channel active pattern are formed in the first region, and
the semiconductor device further comprises a third multi-channel active pattern, on the substrate in the second region, being spaced apart from the substrate, and having a third height that is less than the first height.

10. The semiconductor device of claim 9, further comprising a field insulating film on the substrate,
wherein the field insulating film is interposed between the substrate and the second multi-channel active pattern, and between the substrate and the third multi-channel active pattern.

11. The semiconductor device of claim 9, wherein the second multi-channel active pattern includes a different material from the third multi-channel active pattern.

12. The semiconductor device of claim 9, wherein the first region is a region where a first conductivity type transistor is formed, and the second region is a region where a second conductivity type transistor, different from the first conductivity type transistor, is formed.

13. A semiconductor device, comprising:
a first multi-channel active pattern having a first height on a substrate;
a second multi-channel active pattern on the substrate, having a second height that is less than the first height;
a field insulating film on the substrate, partially covering a sidewall of the first multi-channel active pattern and a sidewall of the second multi-channel active pattern; and
a gate electrode on the field insulating film, intersecting the first multi-channel active pattern and the second multi-channel active pattern,
wherein a height from the substrate to an uppermost portion of the first multi-channel active pattern is equal to or less than a height from the substrate to an uppermost portion of the second multi-channel active pattern.

14. The semiconductor device of claim 13, wherein a height at which the field insulating film covers the sidewall of the first multi-channel active pattern is greater than a height at which the field insulating film covers the sidewall of the second multi-channel active pattern.

15. The semiconductor device of claim 13, wherein the field insulating film is interposed between the substrate and the second multi-channel active pattern, and is not interposed between the substrate and the first multi-channel active pattern.

16. A semiconductor device comprising:
a first multi-channel active pattern having a first height on a substrate, the first multi-channel active pattern being spaced apart from the substrate;
a second multi-channel active pattern having a second height on the substrate, the second multi-channel active pattern being spaced apart from the substrate, the second height being different from the first height;
a field insulating film on the substrate, covering a sidewall of the first multi-channel active pattern and a sidewall of the second multi-channel active pattern, interposed between the second multi-channel active pattern and the substrate; and
a gate electrode on the substrate, intersecting the first multi-channel active pattern and the second multi-channel active pattern.

17. The semiconductor device of claim 16, wherein the field insulating film is formed along a perimeter of the first multi-channel active pattern and along a perimeter of the second multi-channel active pattern.

18. The semiconductor device of claim 17, further comprising a third multi-channel active pattern on the substrate, being spaced apart from the substrate, and having a third height that is less than the first height,
wherein the first multi-channel active pattern is located between the second multi-channel active pattern and the third multi-channel active pattern.

19. The semiconductor device of claim 17, wherein the substrate includes a first region and a second region,
wherein the first multi-channel active pattern and the second multi-channel active pattern are formed in the first region,
wherein the semiconductor device further comprises a third multi-channel active pattern, on the substrate in the second region, being spaced apart from the substrate, and having a third height that is less than the first height, and
wherein the first region is a region where a first conductivity type transistor is formed, and the second region is a region where a second conductivity type transistor, different from the first conductivity type transistor, is formed.

20. The semiconductor device of claim 19,
wherein the field insulating film is interposed between the substrate and the third multi-channel active pattern, and
wherein the second multi-channel active pattern includes a different material from the third multi-channel active pattern.
